(19) United States
(12) Patent Application Publication
(10) Pub. No.: US 2008/0096016 A1
(43) Pub. Date: Apr. 24, 2008

(54) LAMINATED BODY USED TO PRODUCE PRINTED WIRING BOARD, AND METHOD OF PRODUCING PRINTED WIRING BOARD USING THE SAME

(75) Inventor: Mitsuyuki TSURUMI, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/875,609

(22) Filed: Oct. 19, 2007

(30) Foreign Application Priority Data
Oct. 20, 2006 (JP) 2006-286443

(51) Int. Cl. H05K 3/00; B32B 7/12

(52) U.S. Cl. 428/344; 427/98.4

(57) ABSTRACT

The present invention provides a laminated body for producing a printed wiring board, which includes an adhesive layer that is provided between an insulating film for a printed wiring board and a metal film for forming wiring. The adhesive layer includes an active species generating composition that is capable of generating an active species having reactivity by energy application, and a polymer precursor composition that includes a compound capable of forming a polymer compound by reaction with the active species generating composition. The invention also provides a method of producing a printed wiring board.

### CROSS-REFERENCE TO RELATED APPLICATION

This Application claims priority under 35 USC 119 from Japanese Patent Application No. 2006-286443, the disclosure of which is incorporated by reference herein.

### BACKGROUND OF THE INVENTION

1. Field of the Invention

The present invention relates to a laminated body for producing a printed wiring board and a method of producing the printed wiring board. In particular, the invention relates to a laminated body for producing a printed wiring board having high density wiring that is used in the field of electronic materials, and a method of producing a printed wiring board that can form high density wiring by using the laminated body.

2. Description of the Related Art

With demands for high performance electronic devices in recent years, electronic components are being increasingly highly integrated and mounted at higher densities. For this reason, printed wiring boards applicable to the increasingly high levels of integration and high mounting densities are also reducing in size and increasing in density. Various methods, such as a method of forming stable high-definition wiring and a method using a multilayer build-up wiring board, are being examined to accommodate increasing integration of the printed wiring boards. However, multilayer build-up wiring boards have the problem that when heat and pressure bonding is carried out to multilayer build-up wiring boards, there is a concern that the connection strength decreases between layers joined by fine vias.

“Subtractive methods” are known as methods of forming metal patterns, which is useful for conductive patterns, particularly in the field of printed wiring board. In subtractive methods, a photosensitive layer, which is photosensitive to irradiation with actinic light, is formed on a metal layer that is formed on a substrate. After that, the photosensitive layer is exposed with an image pattern, and then developed to form a resist image. Subsequently, metal patterns are formed by etching metal, and the resist is then stripped of. With the metal substrates which are used in subtractive methods, the interface of the substrates is embossed to give adhesion between the substrate and the metal layer so that an adhesion is generated due to an anchor effect. As a result, the substrate interface of the metal patterns is uneven, and when the metal patterns are used as electric wiring, there is a problem in that high frequency characteristics deteriorate. Further, when a metal substrate is formed, since embossing processing is carried out to the substrate, there has been a problem in that a troublesome process is required for processing the substrate with a strong acid, such as a chromium acid.

In order to solve these problems, a method has been proposed including grafting a radical polymerizable compound onto the surface of a substrate in order to modify surface properties thereof, thereby minimizing the unevenness of the substrate and simply and easily processing the substrate (for example, see Japanese Patent Application Laid-Open (JP-A) No. 58-196238). However, expensive pieces of apparatus (a γ-ray generator or an electron ray generator) are required with this method.

Recently, nanotechnology materials have come into the spotlight as an innovative technology of the 21st century. In particular, a technology for manufacturing a film in which nanoparticles are accumulated and stacked has come into the spotlight as a new material technology, being useful in various industrial fields such as conductive films, optical films, biosensors, and gas barrier films (for example, see Shipway, A. N. et al., Chem. Phys. Chem., Vol. 1, p 18 (2000) and Templeton, A. C. et al., Acc. Chem. Res., Vol. 33, p 27 (2000)). In this research, it has been pointed out that the development of a one-step process for continuously forming a thin film by accumulating, arranging, and depositing manufactured nanoparticles onto a substrate is practically important, as well as a method of stably manufacturing nanoparticles in which the size distribution, chemical composition, and the like thereof are sufficiently controlled. In the related art, a method of stacking particles by a multi-step process (layer-by-layer LBL method) has been known as a technology for accumulating, arranging, and depositing nanoparticles onto the surface so as to fix the nanoparticles (for example, see Brust, M. et al., Langmuir, vol 14, p 5425 (1998)). If this method is used, it is possible to produce a regular multilayered structure. However, the processes of the method are complicated, and the method is not suitable as a practical technique for producing a layer of particles.

As a method of accumulating particles, there has been proposed a method that includes forming hydrophilic/hydrophobic regions on the surface of the substrate in the shape of a pattern by using a surface graft polymer with the polymer terminals thereof fixed to the surface of a substrate, and adhering conductive materials in accordance with the pattern, thereby providing a conductive pattern material (for example, see JP-A No. 2003-114525). In this method, the conductive materials are adhered to the surface of the substrate by using graft polymers, which are strongly bonded to the surface of a chosen substrate. This method is useful for forming high-definition pattern, but there is room for improvement in terms of the adhesive strength of the conductive material.

### SUMMARY OF THE INVENTION

The present invention has been made in view of the above circumstances.

That is, the invention provides a laminated body for producing a printed wiring board where a conductive film that has excellent adhesion between the insulating film and itself and high definition can be easily formed on the surface of a chosen solid body.

Further, the invention provides a method of producing a printed wiring board, which has excellent adhesion and high-definition wiring on a substrate, using the laminated body for producing a printed wiring board.

The inventor has identified the use of a laminated body including a specific adhesive layer between a substrate and a metal film (conductive film), and thereby completed the invention.

According to a first aspect of the invention, there is provided a laminated body for producing a printed wiring board. The laminated body includes an adhesive layer that is provided between an insulating film for a printed wiring board and a metal film for forming wiring. The adhesive layer includes an active species generating composition that is capable of generating an active species having reactivity by energy application, and a polymer precursor composition that includes a compound capable of forming a polymer compound by reaction with the active species generating composition.

According to a second aspect of the invention, there is provided a method of producing a printed wiring board. The method includes: applying, on a surface of an insulating film for a printed wiring board, a coating liquid for forming an adhesive layer, the coating liquid including an active species generating composition that is capable of generating an active species having reactivity by energy application and including a polymer precursor composition that includes a compound capable of forming a polymer compound by reaction with the active species generating composition; drying the coating liquid to form an adhesive layer; and forming a metal film capable of forming wiring, on a surface of the adhesive layer.

According to a third aspect of the invention, there is provided a method of producing a printed wiring board. The method includes: forming an adhesive layer by sequentially applying on a surface of an insulating film for a printed wiring board an active species generating layer coating liquid that is capable of generating an active species having reactivity by energy application, and a polymer precursor layer coating liquid that includes a compound capable of forming a polymer compound by reaction with the active species generating layer coating liquid; and forming a metal film capable of forming wiring, on a surface of the adhesive layer.

According to a forth aspect of the invention, there is provided a method of producing a printed wiring board. The method includes: forming an adhesive layer by sequentially laminating on a surface of an insulating film for a printed wiring board an active species generating layer made of an active species generating composition that is capable of generating an active species having reactivity by energy application, and a reactive polymer precursor layer that includes a compound capable of forming a polymer compound by the reaction with the active species generating layer; and forming on a surface of the adhesive layer a metal film capable of forming wiring.

According to a fifth aspect of the invention, there is provided a method of producing a printed wiring board. The method includes placing a laminated body for producing a printed wiring board according to the first aspect, on or above a substrate; and then forming a polymer generation region by applying energy and generating a polymer compound which is directly bonded to the active species generating layer, improving adhesiveness between the substrate and the metal film by the generated polymer compound.

If the laminated body for producing a printed wiring board according to the invention is used, it is possible to efficiently form fine wiring by forming, on a insulating film layer, an adhesive layer that has excellent adhesion between the metal film and itself, without damaging conventional low dielectric layers and without the need to roughen the surface of the insulating film, such as a substrate.

It is possible to improve the adhesion to the metal film over the entire surface of the insulating film by performing energy application (exposure), which improves the adhesion of the adhesive layer, to the entire surface of the insulating film. Further, it is possible to achieve improved adhesion at wiring that is of high-definition in accordance with the exposure accuracy by applying energy in the shape of a pattern.

In the laminated body, it is preferable that the insulating film (insulating material) forming a substrate is an insulating resin including a polymerization initiator, and the polymer precursor layer includes a compound having a polymerizable double bond that is able to form a graft polymer that has been directly bonded to the surface of the insulating film by energy application. It should be noted that, in the invention, the insulating film need not necessarily be formed of a material containing a compound having a polymerization initiator and a polymerizable double bond as described in the preferred embodiments, and any material may be used to form the insulating film as long as it forms a graft polymer directly bonded to the insulating film or to the active species generating layer that is strongly adhered to the insulating film.

Printed wiring boards with high-definition wiring obtained by the method according to the invention have fine wiring patterns with excellent high frequency characteristics, and may also be suitably applied to multilayered wiring boards. In addition, these printed wiring boards are useful for various electronic devices and electric devices.

### DETAILED DESCRIPTION OF THE INVENTION

A laminated body for producing a printed wiring board according to the present invention includes an adhesive layer provided on the surface of a base material. The adhesive layer includes an active species generating composition that is capable of generating an active species by energy application such as exposure, and a polymer precursor composition having reactivity that is capable of forming a polymer compound (graft polymer) by reaction with the active species.

In this case, if an insulating film of the adhesive layer has an active species generating function for generating an active species by energy application, the insulating film itself may function as an adhesive layer. However, the adhesive layer preferably has a layered structure that includes an active species generating layer and a polymer precursor layer. The active species generating layer is capable of generating an active species by energy application, and the polymer precursor layer contains a compound capable of forming a polymer compound by the reaction with the active species generating layer.

In this specification, the “active species generating layer that is capable of generating an active species by energy application” is referred to as an “(A) layer” or an “active species generating layer”, and the “polymer precursor layer having reactivity” is referred to as a “(B) layer” or a “polymer precursor layer”.

Further, in order to protect the adhesive layer until the adhesive layer is used, it is preferable that a protective layer be formed on the surface of the laminated body after the formation of the adhesive layer.

In the laminated body of the present invention, when being used, the adhesive layer may be disposed in such a manner that the (A) layer directly comes in contact with the insulating film for forming the wiring and the (B) polymer precursor layer is disposed on the other surface of the (A) layer, the surface opposite to the surface at which the insulating film is disposed. Furthermore, if the insulating film has an active species generating function for generating an active species by energy application, the insulating film may be used as the (A) layer.

Layers forming a laminated body for producing a printed wiring board according to the invention will be sequentially described below.

First, the adhesive layer will be described.

### [Adhesive Layer]

The laminated body for producing a printed wiring board according to the invention includes an insulating film for the printed wiring board, a metal film for forming wiring, and an adhesive layer therebetween. The adhesive layer contains an active species generating composition that is capable of generating an active species having reactivity by energy application, and a polymer precursor composition that contains a compound capable of forming a polymer compound by the reaction with the active species generating composition.

The adhesive layer preferably has a layered structure that includes an active species generating layer [(A) layer] and a polymer precursor layer [(B) layer]. The active species generating layer is capable of generating an active species by energy application, and the polymer precursor layer includes a compound capable of forming a polymer compound by the reaction with the active species generating layer.

The adhesive layer can be formed by applying a coating liquid for forming an adhesive layer including an active species generating composition and a polymer precursor composition, on the surface of the insulating film for the printed wiring board, and drying the compositions.

Examples of the methods of forming an adhesive layer include a method including sequentially applying a coating liquid including an (a) active species generating composition and a coating liquid containing a (b) polymer precursor composition on the surface of the insulating film for producing the printed wiring board, to form an adhesive layer which includes an (A) layer and a (B) layer.

Alternatively, the following method may be used as a method of forming an adhesive layer. That is, a coating liquid including an (a) active species generating composition is previously mixed with a coating liquid including a (b) polymer precursor composition, and the liquid mixture thereof is applied, so that an adhesive layer is formed.

It is preferable that the viscosity of the active species generating layer coating liquid including the active species generating composition be in the range of 5 to 5000 cps, and the viscosity of the polymer precursor layer coating liquid including the polymer precursor composition be in the range of 1 to 2000 cps.

A method of forming an adhesive layer is not limited to the above-mentioned application method, and the adhesive layer may be formed by sequentially laminating an active species generating layer [(A) layer] made of an active species generating composition and a reactive polymer precursor layer [(B) layer] that includes a compound capable of forming a polymer compound by the reaction with the active species generating layer.

### [Active Species Generating Composition]

According to the invention, a resin obtained by adding a polymerization initiator to a known insulating resin that has been used for a multilayered wiring board, a buildup substrate, or flexible substrate, is preferably used as the active species generating composition from the viewpoint of an easy grafting reaction with the (B) polymer precursor layer provided in the vicinity thereof. Further, for example, when the known insulating resin itself is a material for generating an active species by energy application, a material not necessarily including a polymerization initiator may be used for the active species generating composition. As long as a material is a compound for forming a graft polymer directly bonded to the insulating film or the active species generating layer being strongly close contact with the insulating film, the material may be used for a material of the active species generating layer.

The insulating resin of the active species generating layer may be the same as or different from an insulating resin used to an insulating film, which is a lower layer. However, a resin having completely or partially the same chemical structure as a resin of the insulating film or a resin having affinity to the insulating resin and itself, such as a resin having the same chemical structure as the insulating resin where an insulating film is partially formed, a resin which is of the same kind as the insulating resin, a resin having excellent compatibility with the insulating resin and itself, and a resin having completely the same structure as the insulating resin, is preferably used as the insulating resin of the active species generating layer.

Further, a polyfunctional acrylate monomer may be added to the resin in order to increase a grafting reactivity or a bonding strength between the insulating layer and the resin. Inorganic or organic particles may be added to the resin as ingredients other than the polyfunctional acrylate monomer in order to increase a bonding strength or electrical characteristics between the insulator layer and the resin.

Ingredients used in the active species generating composition, which is used in the invention, will be sequentially described below.

An epoxy resin, a phenol resin, a polyimide resin, a polyester resin, a bismaleimide resin, a polyolefin-based resin, an isocyanate-based resin, or the like is used as the insulating resin, which is used as a film forming ingredient in the (a) active species generating composition according to the invention. Two or more of the resins may be simultaneously used. For example, as described below, a mixture of a thermosetting resin and a thermoplastic resin may be used.

Examples of the epoxy resin include a cresol novolac epoxy resin, a bisphenol A epoxy resin, a bisphenol F epoxy resin, a phenol novolac epoxy resin, an alkyl phenol novolac epoxy resin, a bisphenol F epoxy resin, a naphthalene epoxy resin, a dicyclopentadiene epoxy resin, an epoxy compound of a condensation product of a phenol and an aromatic aldehyde having a phenolic hydroxyl group, triglycidyl isocyanurate, an alicyclic epoxy resin, and the like. Only one of these resins may be used, or two or more of the resins may be simultaneously used. Since the above-mentioned resins are used, the formed (A) layer is excellent in heat resistance.

Examples of the polyolefin-based resin include a polyethylene-based resin, a polystyrene-based resin, a polypropylene-based resin, a polyisobutylene-based resin, a polybutadiene-based resin, a polyisoprene-based resin, a cycloolefin-based resin, and copolymers of these resins.

In addition, a case when the epoxy resin is used will be described in detail.

The epoxy resin contained in the active species generating composition according to the invention is composed of a reaction product of (a) an epoxy compound having two or more epoxy groups in one molecule and (b) a compound having two or more functional groups, which react to the epoxy group, in one molecule. The functional group of (b) is selected from functional groups, such as a carboxyl group, a hydroxyl group, an amino group, a thiol group, and the like.

The (A) epoxy compound having two or more epoxy groups in one molecule (including resins called epoxy resins) is preferably an epoxy compound having two to fifty epoxy groups in one molecule, and more preferably an epoxy compound having two to twenty epoxy groups in one molecule. In this case, the epoxy group may have an oxirane ring structure, and may be, for example, a glycidyl group, an oxyethylene group, an epoxycyclohexyl group, or the like. The above-mentioned polyvalent epoxy compound has been widely disclosed in, for example, “Epoxy Resin Handbook”, edited by SHIBNO Masaki and published by Nikkan Kogyo Shimbun, Ltd. (1987), and may be used.

Specifically, a bisphenol A epoxy resin, a bisphenol F epoxy resin, a brominated bisphenol A epoxy resin, a bisphenol S epoxy resin, a diphenyl ether epoxy resin, a hydroquinone epoxy resin, a naphthalene epoxy resin, a biphenyl epoxy resin, a fluorene epoxy resin, a phenol novolac epoxy resin, an ortho-cresol novolac epoxy resin, a trishydroxyphenyl methane epoxy resin, a 3-functional epoxy resin, a tetraphenylolethane epoxy resin, a dicyclopentadiene phenol epoxy resin, a hydrogenated bisphenol A epoxy resin, a nuclear polyol epoxy resin containing a bisphenol A, a polypropylene glycol epoxy resin, a glycidyl ester epoxy resin, a glycidyl amine epoxy resin, a glyoxal epoxy resin, an alicyclic epoxy resin, a heterocyclic epoxy resin, or the like may be used.

A polyfunctional carboxylic acid compound such as a terephthalic acid, a polyfunctional hydroxyl group compound such as a phenol resin, and a polyfunctional aminocompound such as an amino resin and 1,3,5-triaminotriazine may be used as the (b) compound having two or more functional groups, which react to the epoxy group, in one molecule.

A hardening agent of an epoxy resin may be included in the resin composition of the invention. Examples of the hardening agent include polyfunctional phenols, amines, imidazole compounds, acid anhydrides, organic phosphorous compounds, and halogenated compounds thereof. However, it is preferable that a material not hindering the chemical reaction with the polymer precursor layer be used as the hardening agent. Further, a hardening accelerator may be added to the active species generating composition of the invention, if necessary. A tertiary amine, an imidazole, a quaternary ammonium salt, or the like may be used as a typical hardening accelerator, but the hardening accelerator is not limited thereto.

For example, a phenoxy resin, polyether sulfon, polysulfone, polyphenylene sulfon, polyphenylene sulfide, polyphenyl ether, polyetherimide, or the like may be used as the thermoplastic resin. (1) 1,2-bis(vinylphenylene)ethane resin(1,2-bis(vinylphenyl)ethane) or a modified resin formed of the 1,2-bis(vinylphenylene)ethane resin(1,2-bis(vinylphenyl)ethane) and a polyphenylene ether resin (disclosed in Journal of Applied Polymer Science Vol. 92, 1252-1258 (2004) written by AMOU satoru), (2) liquid crystalline polymer, specifically, Vecster manufactured by Kuraray Co., Ltd., (3) fluorocarbon polymer (PTFE), or the like may be used as the thermoplastic resin.

### (Mixing of Thermoplastic Resin and Thermosetting Resin)

Only one of the thermoplastic and the thermosetting resins may be used, or two of the thermoplastic and the thermosetting resins may be simultaneously used. The thermoplastic and the thermosetting resins are simultaneously used to make up for their weak points and to obtain more excellent effects. For example, since a thermoplastic resin such as polyphenylene ether (PPE) has a low heat resistance, the thermoplastic resin is alloyed with the thermosetting resin. For example, PPE alloyed with an epoxy or triallyl isocyanurate, a PPE resin in which a polymerizable functional group has been introduced, allowed with another thermosetting resin may be used. Further, cyanate esters have the most excellent dielectric characteristics among the thermosetting resins. However, a cyanate ester is rarely used alone, and is used in the form of a modified resin such as an epoxy resin, a maleimide resin, or a thermoplastic resin. These detailed descriptions are disclosed in Electronic Technology (2002/vol. 9, P35). Further, the thermosetting resin, which includes an epoxy resin and/or a phenol resin, and the thermoplastic resin, which includes a phenoxy resin and/or polyether sulfon (PES), may also be used to improve dielectric characteristics.

### (Compounds Having Polymerizable Double Bond)

Meanwhile, compounds to be required according to uses may be added to the active species generating composition. Examples of these compounds include a compound having a radical polymerizable double bond. Examples of the compound having a radical polymerizable double bond include an acrylate or a methacrylate compound. As long as the acrylate compound [(metha)acrylate] used in the invention has an acryloyl group, which is an ethylenically unsaturated group, in a molecule, the acrylate compound is not specifically limited. However, it is preferable that the acrylate compound be a polyfunctional monomer from viewpoints of improving a hardening ability, hardness, and strength of the formed intermediate layer.

It is preferable that an ester of a polyhydric alcohol and an acrylate acid or a methacrylic acid be used as the polyfunctional monomer. Examples of the polyhydric alcohol include ethylene glycol, 1,4-cyclohexaneol, pentaerythritol, trimethylol propane, trimethylol ethane, dipentaerythritol, 1,2,4-cyclohexaneol, polyurethane polyol, and polyester polyol. Among them, trimethylol propane, pentaerythritol, dipentaerythritol, or polyurethane polyol is preferably used as the polyfunctional monomer. The intermediate layer may contain two or more kinds of polyfunctional monomers. The polyfunctional monomer includes at least two ethylenically unsaturated groups in a molecule. However, more preferably, the polyfunctional monomer may include three or more ethylenically unsaturated groups in a molecule. Specifically, a polyfunctional acrylate monomer, which includes three to six acrylic acid ester groups in a molecule, may be used. An oligomer including an acrylic acid ester group in a molecule and having a molecular weight of several hundreds to several thousands, such as the compound called urethane acrylate, polyester acrylate, or epoxy acrylate, may also be preferably used as an ingredient of the intermediate layer of the invention.

Specific examples of the acrylate, which includes three or more acrylic groups in a molecule, include polyol polyacrylates, such as trimethylol propane triacrylate, ditrimethylol propane tetraacrylate, pentaerythritol triacrylate, pentaerythritol tetraacrylate, dipentaerythritol pentaacrylate, dipentaerythritol hexaacrylate; and urethane acrylate, which is obtained due to the reaction of a polyisocyanate and an acrylate containing a hydroxyl group such as polyol polyacrylates, such as hydroxyethyl acrylate. In addition, a thermosetting resin or a thermoplastic resin, for example, a resin obtained by a part of an epoxy resin, a phenol resin, a polyimide resin, a polyolefin resin, a fluoro resin or the like is (metha)acrylically reacted by adding a methacrylic acid or an acrylate acid, may be used as a compound having polymerizable double bond. Specifically, a (metha)acrylate compound of an epoxy resin may be used.

It is preferable that these insulating resins be contained in an active species generating composition in an amount of 5 to 100 mass % relative to a solid content of the active species generating composition.

### (Kind of Polymerization Initiators Added to Active Species Generating Composition)

Any one of a thermal polymerization initiator and a photopolymerization initiator may be used as the polymerization initiator, which is used in the (A) active species generating composition, in the invention. A peroxide initiator such as a benzoyl peroxide or azoisobutyronitrile, or an azo-based initiator may be used as the thermal polymerization initiator. Further, any one of a low-molecular weight initiator, a polymer, or a generally known initiator may be used as the photopolymerization initiator.

For example, a known radical generator, such as an acetophenone, a benzophenone, a Michler's ketone, a benzoylbenzoate, a benzoin, α-acyloxime ester, tetramethylthiuram monosulfate, trichloromethyl triazine, or thioxanthone, may be used as a low-molecular weight photopolymerization initiator. Further, since a sulfonium salt and an iodonium salt, which are used as a photoacid generator generally, function as a radical generator through the light irradiation, a sulfonium salt or an iodonium salt may be used in the invention. Furthermore, a sensitizer may be used in addition to the photo-radical polymerization initiator to improve sensitivity. Examples of the sensitizers include n-butylamine, triethylamine, tri-n-butylphosphine, and thioxanthone derivatives.

A polymer compound, which is disclosed in JP-A Nos. 09-77891 and 10-45927 and has an active carbonyl group on a side chain thereof, can be used as a polymer photo-radical generator.

The amount of the polymerization initiator contained in the active species generating composition is determined according to uses of the surface graft material to be used. However, in general, it is preferable that the amount of the polymerization initiator be about 0.1 to 50 mass % of a solid content in the insulator layer, and it is more preferable that the amount of the polymerization initiator be about 1.0 to 30.0 mass % of a solid content in the insulator layer.

### (Other Additive Agents Contained to Active Species Generating Composition)

According to the invention, a composite (composite material) formed of a resin and other ingredients may be used in the (A) layer in order to improve characteristics such as a mechanical strength, a heat resistance, an antiweatherability, a fire retardancy, a water resistance, and an electrical characteristic of a resin film. Paper, fiberglass, silica particles, a phenol resin, a polyimide resin, a bismaleimide triazine resin, a fluoro resin, a polyphenylene oxide resin, or the like may be used as a material used for the composite.

Further, fillers used in a resin material for a general wiring board may be contained in the active species generating composition, as necessary. Examples of the fillers include inorganic fillers, such as a silica, alumina, clay, talc, aluminum hydroxide, and calcium carbonate, and organic fillers, such as a hardened epoxy resin, a crosslinked benzoguanamine resin, and a crosslinked acrylic polymer. One or more of the fillers may be contained in the active species generating composition.

In addition, one or two or more of additive agents, such as a coloring agent, a fire retardant, an adhesiveness applying agent, a silane coupling agent, an anti-oxidizing agent, and an ultraviolet absorbing agent, may be added to the active species generating composition, if necessary.

When these materials are added to the active species generating composition, it is preferable that the amount of any material be in the range of 1 to 200 mass % with respect to the amount of the resin and it is more preferable that the amount of any material be in the range of 10 to 80 mass % with respect to the amount of the resin. When the amount of added material is smaller than 1 mass %, the above-mentioned characteristics may not be improved. Meanwhile, when the amount of added material is larger than 200 mass %, a characteristic such as strength of a resin may deteriorate and further, a grafting reaction may not proceed.

### (Formation of Active Species Generating Composition Layer)

The (A) active species generating composition is a material used to form an active species generating layer of the adhesive layer, and it is preferable that the thickness of the active species generating composition layer according to the invention be in the range of 0.5 to 50 μm.

From the viewpoint of improving physical properties of the formed active species generating composition layer, it is preferable that an average roughness (Rz) of the layer measured using a 10-point average height method disclosed in JIS B 0601 (1994), the disclosure of which is incorporated by reference herein, be 3 μm or less, and it is more preferable that the average roughness (Rz) be 1 μm or less. If a surface smoothness of the substrate is in the above-mentioned range, that is, the substrate substantially does not have unevenness, the substrate may preferably be used to produce a printed wiring board having an extremely fine circuit (for example, a circuit pattern of which values of line/space are 25/25 μm or less).

Further, from a similar viewpoint, it is preferable that the smoothness of the substrate to be used be also in the above-mentioned range when wiring is formed on the substrate by using the laminated body according to the invention.

### (A) Formation of Active Species Generating Composition Layer

The (A) layer may be formed by directly applying a coating liquid, which is prepared by dissolving the above-mentioned ingredients in a suitable solvent so as to have improved coating characteristics, on the surface of the insulating film for producing the printed wiring board used as a support or a substrate, and then drying the coating liquid. Further, previously formed active species generating layer may be laminated to form the (A) layer. Furthermore, active species generating layer (sheet-shaped layer) used in the laminating method may also be formed by applying a coating liquid, which is used to form an active species generating layer, on the suitable surface of the support, and then drying the coating liquid. When the active species generating layers are formed beforehand in the shape of a film as described above, thickness accuracy, handleability, and positioning accuracy are improved. Therefore, it is possible to preferably use the layers.

Water or an organic solvent is used as a solvent applied to form the active species generating layer. Any one of a hydrophilic solvent and a hydrophobic solvent may be used as the organic solvent. In particular, a solvent having a high hydrophobicity may be used as the organic solvent. Further, a solvent for dissolving a thermosetting resin, a thermoplastic resin, or a precursor for forming the resin after reaction, for forming the active species generating layer, may be used as the organic solvent. Specifically, an alcohol-based solvent, such as methanol, ethanol, 1-methoxy-2-propanol, or isopropyl alcohol, a ketone-based solvent, such as aceton, methyl ethyl ketone, or cyclohexaneone, an ether-based solvent, such as ethylene glycol monomethyl ether, ethylene glycol-mono-n-butyl ether, ethylene glycol monoethyl ether, or tetrahydrofuran, a nitrile-based solvent such as acetonitrile, or an ester-based solvent, such as ethyl acetate, butyl acetate, isopropyl acetate, or ethylene glycol monoethyl ether acetate may be preferably used. Further, N-methyl-2-pyrolidone, N,N-dimethyl acetamide, N,N-dimethylformamide, ethylene glycol monomethyl ether, or tetrahydrofuran may also be used. Furthermore, solvents having low polarity such as benzen, toluene, xylene, naphthalene, hexan, and cyclohexane may be used, as long as the solvent can dissolve an active species generating composition.

The amount of the active species generating composition included in the coating liquid is determined depending on the purpose. From the viewpoint of a workability, coating characteristics, drying time, and a working efficiency during the formation of the active species generating layer to be obtained, it is preferable that the viscosity of the composition be adjusted in the range of 5 to 5000 cps, and it is more preferable that the viscosity of the composition be adjusted in the range of 10 to 2000 cps, and it is still more preferable that the viscosity of the composition be adjusted in the range of 10 to 1000 cps. The viscosity is measured using a viscometer (trade name: RE80, manufactured by Toki Sangyo Co. Ltd.), and a rotor 30XR14 at a temperature of 28° C.

In a method of preparing a composition, the solvent and ingredients of the composition are mixed using a known method using a mixer, a beads mill, a pearl mill, a kneader, or three rolls to prepare a composition. All of the various composition ingredients may be added at the same time, may be added in a proper order, or if necessary, a part of the composition ingredients may be previously mixed and the other composition ingredients may be added.

Application for forming the active species generating layer may be performed by a general method. For example, a known application method, such as a blade coating method, a rod coating method, a squeeze coating method, a reverse roll coating method, a transfer roll coating method, a spin coating method, a bar coating method, an air knife method, a gravure printing method, or a spray coating method, is used.

A method of removing a solvent is not particularly limited, but it is preferable that a solvent be removed by the evaporation of the solvent. Examples of the evaporation method include a heating method, a pressure reducing method, and a ventilation method. From viewpoints of a production efficiency and handleability, a method of evaporating the solvent by heating among the methods is preferable, and a method of evaporating the solvent by heating the solvent while ventilating the solvent is more preferable. For example, it is preferable that a solvent be coated on one surface of the support to be described below, and heated and dried at a temperature of 80 to 200° C. for a period of 0.5 to 10 min to remove the solvent, thereby forming a nonsticky and semi-hardened film.

### [Reactive Polymer Precursor Composition]

The polymer precursor composition contains one or more kinds of polymer precursors. The polymer precursor mentioned here means a compound (polymerizable compound) that is capable of generating a graft polymer by energy application such as exposure, or a compound that forms a crosslinked structure between adjacent layers by energy application and may improve the adhesion of the layers. The polymer precursor further includes a functional group capable of interacting with a conductive material, which is a partial structure to which a conductive material to be described below is adhered. The polymer compound (hereinafter, sometimes referred to as a “graft polymer”), which is generated by a reactive compound by the reaction of the polymer precursor, has a function to improve adhesion to a metal film such as a conductive material. Accordingly, it is preferable that the polymer precursor be capable of a polymerization reaction or forming a crosslinked structure, and that the polymer precursor be a compound, which includes a partial structure required to be bonded to the active species generating composition layer, for example, “radical polymerizable unsaturated double bond” and “a functional group capable of interacting with the conductive material” required to adhere a conductive material to be described below to a graft polymer.

### (Polymerizable Compound)

A polymerizable compound capable of being polymerized may be used as a representative one among the polymer precursors. The polymerizable compound is a compound that has a radical polymerizable unsaturated double bond in a molecule.

Examples of a functional group including the “radical polymerizable unsaturated double bond” include a vinyl group, a vinyl oxy group, an allyl group, an acryloyl group, a methacryloyl group. Among these examples, an acryloyl group and a methacryloyl group each have high reactivity and excellent results can be obtained.

Any compound may be used as a radical polymerizable unsaturated compound, as long as the compound includes a radical polymerizable group. Examples of the radical polymerizable unsaturated compound include a monomer or a macromer including an acrylate group, a methacrylate group, or a vinyl group, or an oligomer or a polymer including a polymerizable unsaturated group.

Further, an oligomer, a polymer compound, or a combination of a crosslinking agent and a crosslinking compound may be used as another example of the polymer precursor. The oligomer or the polymer compound includes a reactive activating group, which is represented by, for example, an epoxy group, an isocyanate group, and an azo group, in a molecule.

The polymer precursor needs to include a functional group capable of interacting with a conductive material, which is a partial structure to which a conductive material is adhered.

A functional group, such as ammonium or phosphonium, that has positive charges, or an acid group, such as a sulfonic acid group, a carboxyl group, a phosphate group, or a phosphonic acid group, that has negative charges or separated due to negative charges is used as the functional group capable of interacting with the conductive material. In addition, for example, a nonionic polar group, such as a hydroxyl group, an amide group, a sulfonamide group, an alkoxy group, or a cyano group may be used as the functional group capable of interacting with the conductive material.

A hydrophilic group or a functional group, which is capable of interacting with an electroless plating catalyst or the precursor thereof, is used as a functional group having affinity to a conductive material.

The polymer precursor, which is an ingredient of the (B) polymer precursor layer according to the invention, will be described in detail with reference to a polymerizable compound, which is a representative one of the polymer precursor. A polymerizable compound, which includes a radical polymerizable unsaturated double bond and a functional group capable of interacting with a conductive material, may be a low-molecule weight compound or a polymer compound. When the polymerizable compound is a polymer compound, an average molecular weight may be in the range of 1000 to 500000. The above-mentioned polymer compound is obtained using additional polymerization such as usual radical polymerization or anion polymerization, or polycondensation.

Specifically, according to the invention, a hydrophilic polymer, a hydrophobic polymer, a hydrophilic macromer, a hydrophobic macromer, a hydrophilic monomer, a hydrophobic monomer, or the like may be used as a compound that includes a radical polymerizable unsaturated double bond (hereinafter, properly referred to as a “polymerizable unsaturated group”) and a functional group capable of interacting with the conductive material, as long as the compound can adhere and adsorb metal ions or metal salt. However, in terms of the easy formation of the (B) polymer precursor layer, it is preferable that a polymer or a macromer be used.

When a macromonomer or a polymer is used as a polymerizable compound, it is easy to prepare liquid composition containing a polymerizable compound having viscosity suitable for forming a layer by using a coating liquid method. Further, it is possible to easily form the (B) polymer precursor layer on the (A) active species generating layer in the laminated body according to the invention by applying and drying the liquid composition.

Meanwhile, when a hydrophilic monomer is used as the polymerizable compound, it is preferable that a binder or the like be used in the (B) polymer precursor layer in order to form a stable coated film. Alternatively, a coated film, which is made of liquid composition and has low viscosity, is preferably coated with a protective layer to be described below to facilitate the stabilization of the layer.

Accordingly, if a macromonomer or a polymer is used as a polymer precursor it is possible to easily form the (B) polymer precursor layer having a uniform thickness. As a result, it is understood that a uniform graft polymer generation region may be formed. Therefore, if the laminated body according to the invention is formed by using a macromonomer or a polymer as a polymerizable compound, it is possible to obtain a printed wiring board where a conductive layer having excellent conductivity and uniformity is easily formed by using the laminated body.

As described above, from the viewpoint of manufacturability, it is preferable that a macromonomer or a polymer be used as a polymerizable compound and a solution thereof be applied and then dried on the surface of the (A) active species generating layer to form the (B) polymer precursor layer. However, the (B) layer may be formed beforehand and then laminated on the surface of the (A) layer.

It is preferable that a polymer precursor represented by the polymerizable compound be contained in the polymer precursor composition forming the (B) layer in an amount of about 5 to 100 mass %, and it is more preferable that the polymer precursor be contained in the polymer precursor composition in an amount of 30 to 100 mass

### (Other Ingredients Used in Polymer Precursor Layer)

As long as the effect of the invention does not deteriorate, the (B) polymer precursor layer may contain various compounds, such as, a binder, a plasticizer, a surfactant, and a viscosity modifier, which are used to improve film properties, in addition to the polymerizable compound.

### (Binder)

A binder may be used to form the (B) polymer precursor layer together with a hydrophilic compound containing a radical polymerizable group, and is useful for the improvement of the film properties. When a layer is formed of only a polymerizable group compound, the binder is not needed. However, in order to use a monomer having low viscosity as a polymerizable compound, from the viewpoint of improving the layer formability, it is preferable that the binder be used. The binder used for this purpose is not particularly limited as long as it can be mixed with a hydrophilic compound containing polymerizable groups and can form a film. However, it is preferable that an oligomer or a polymer having a molecular weight of 500 or more be used as a binder.

Examples such polymer include synthetic polymers such as a (metha)acrylate-based polymer (for example, a polyacrylic acid, a polymethacrylic acid, polyvinyl alcohol, polybutyral, polyvinyl pyrolidone, polyethyleneoxide, polyethylenimine, polyacrylamide, carboxy-methyl cellulose, and hydroxyethyl cellulose), a cellulose-based polymer, polystyrene, polyethylene, polybutadiene, nylon, polyamide, polymethylmethacrylate, polyvinyl chloride, polycarbonate, polyacrylonitrile, polyester, polypropylene, an aramid resin, and copolymers of these polymers; and natural hydrophilic polymers, such as gelatine, starch, an arabic gum, and sugar.

When the binder is used together with other materials, it is preferable that the amount of the binder be in the range of 0 to 95 mass % relative to a solid content and it is more preferable that the amount of the binder be in the range of 0 to 70 mass % relative to a solid content.

### (Plasticizer, Surfactant, and Viscosity Modifier)

These compounds may be used to improve properties of the coated surface when a film of the (B) polymer precursor layer is formed, or to give flexibility to a film so as to suppress the occurrence of cracks when the film is bent or the like. Materials, which are widely used and known, may be used as a plasticizer, a surfactant, or a viscosity modifier.

### (Formation of Polymer Precursor Layer)

The (B) polymer precursor layer is formed by applying and drying a coating liquid, which is prepared by dissolving the ingredients in a suitable solvent, on the (A) active species generating layer or the surface of a suitable support when a laminating method is used.

Water or an organic solvent is used as the solvent. Any one of a hydrophilic solvent and a hydrophobic solvent may be used as the organic solvent. However, it is preferable that a solvent which is difficult to dissolve an initiator layer or a solvent which is difficult to be mixed with an initiator layer be used. For example, when a solvent having high hydrophobicity is used in the initiator layer, it is preferable that a solvent having slight hydrophobicity be used. Specifically, an alcohol-based solvent, such as methanol, ethanol, or 1-methoxy-2-propanol, a ketone-based solvent, such as aceton, methyl ethyl ketone, or cyclohexaneone, an ether-based solvent, such as ethylene glycol monomethyl ether, ethylene glycol-mono-normal butyl ether, ethylene glycol monoethyl ether, or tetrahydrofuran, a nitrile-based solvent such as acetonitrile, or an ester-based solvent, such as ethyl acetate, butyl acetate, isopropyl acetate, or ethylene glycol monoethyl ether acetate may be preferably used. In addition, N-methyl-2-pyrolidone, N,N-dimethyl acetamide, N,N-dimethylformamide, ethylene glycol monomethyl ether, or tetrahydrofuran may also be used. Further, a mixed solvent where these solvents and water are mixed may be used.

The concentration of the solid ingredient of the coating liquid is determined depending on the purpose. However, from viewpoints of properties of the interface between the (A) layer and the coating liquid and workability during the application, it is preferable that the viscosity of the coating liquid be adjusted in the range of 1 to 2000 cps, it is more preferable that the viscosity of the coating liquid be adjusted in the range of 3 to 1000 cps, and it is still more preferable that the viscosity of the coating liquid be adjusted in the range of 5 to 700 cps.

Application is performed by a general method. For example, a known application method, such as a blade coating method, a rod coating method, a squeeze coating method, a reverse roll coating method, a transfer roll coating method, a spin coating method, a bar coating method, an air knife method, a gravure printing method, or a spray coating method, may be used to perform application.

It is preferable that the thickness of the reactive polymer precursor layer be in the range of 0.5 to 10 μm. In this range, it is possible to obtain the thickness of a graft polymer layer to be formed thereafter in a preferable range, and it is possible to ensure excellent adhesion between the conductive material and the reactive polymer precursor layer, for example, when a conductive material is adhered during the following process.

The thickness of the graft polymer layer, which is generated by energy application such as exposure, after the formation of the polymer precursor layer, is preferably in the range of 0.5 to 10 μm. Accordingly, when the polymer precursor layer has a thickness larger than 10 μm, the amount materials not related to the formation of the graft polymer become much, so that cost increases. In addition, an exposure source rarely reaches deep portions, and it may be difficult to remove unnecessary graft polymer precursor materials.

The adhesive layer having the layered structure, which includes the above-mentioned (A) active species generating layer and the (B) polymer precursor layer, may be formed directly on the surface of the insulating film for the printed wiring board to be described below, by using a sequential application method. Accordingly, it is possible to obtain a laminated body. However, when the adhesive layer is formed on the surface of the insulating film for the printed wiring board by using a laminating method, the (A) layer and the (B) layer of the adhesive layer may be formed beforehand on the surface of a suitable support. The support used in the above-mentioned case will be described below.

### [Support]

The adhesive layer of the laminated body for the printed wiring board according to the invention includes at least the (A) layer and the (B) layer, which are provided between a support used as a base film and a protective layer to be described below. Further, when it is used, the adhesive layer can be applied on an insulating film of the printed wiring board by using a laminating method. When the laminated body according to the invention is formed, a side of the support having the adhesive layer, which can be used in the laminating method, facing the (A) layer comes in contact with the predetermined insulating film for the printed wiring board and the support is used as a base of the adhesive layer until the formation of the adhesive layer.

A resin sheet, which is made of polyolefin, such as polyethylene, polypropylene, or polyvinyl chloride, polyester such as polyethylene terephthalate, polyamide, polyimide, or polycarbonate, a processed paper, of which surface adhesiveness is controlled, such as exfoliate paper, or a metal foil, such as a copper foil or an aluminum foil may be used as the base film used as the support.

The thickness of the support is generally in the range of 2 to 200 μm. However, it is preferable that the thickness of the support be in the range of 5 to 50 μm, and it is more preferable that the thickness of the support be in the range of 10 to 30 μm. If the sheet used as the support is too thick, there is a problem in handling ability when wiring is actually formed using the laminated body, specifically, when the laminated body is laminated on a predetermined substrate or wiring.

Further, a mat treatment, a corona treatment, and a mold-release treatment may be performed on the surface of the sheet forming the support.

If the width of the support is set to be larger than that of the insulating film or the polymer precursor layer by about 5 mm, it is possible to prevent a resin from being attached to a laminate portion when other layers and the support are laminated. Further, there is an advantage that a supporting base film is easily stripped during the use.

### [Protective Layer]

The same material as the material of the support, or a different material from the material of the support may be used as a resin film used to form a protective layer. A resin sheet, which is made of polyolefin, such as polyethylene, polyvinyl chloride, or polypropylene, polyester such as polyethylene terephthalate, polyamide, polyimide, or polycarbonate, a processed paper, of which surface adhesiveness is controlled, such as exfoliate paper, or a metal foil, such as a copper foil or an aluminum foil may be used as a preferable material of the protective layer.

The thickness of the protective layer (protective film) is generally in the range of 2 to 150 μm. However, it is preferable that the thickness of the protective layer be in the range of 5 to 70 μm, and it is more preferable that the thickness of the protective layer be in the range of 10 to 50 μm. Further, one of the protective film and the supporting base film may be thicker than the other.

A mat treatment, an embossing, and a mold-release treatment may be performed on the protective film.

The protective film may be disposed on the adhesive layer before being used to form the laminated body for producing a printed wiring board according to the invention, and may be wound and stored in the form of a roll.

### [Insulating Film for Printed Wiring Board]

In the laminated body according to the invention, a metal film is disposed on the surface of the insulating film for the printed wiring board with the adhesive layer therebetween. The insulating film for producing the printed wiring board may be an insulating substrate in the case of a single layered printed wiring board, and may be an insulating resin layer formed on the wiring that is formed beforehand in the case of a second or higher layer of a multilayered printed wiring board.

Known insulating resins, which are used for a multilayered board, a buildup substrate, and a flexible substrate, may be used to form the insulating film for the printed wiring board. These resins include thermosetting resins, thermoplastic resins, or resin mixtures thereof. These resins may be used without modification in the invention. However, these resins may contain various compounds, which are added depending on the purpose. For example, a polyfunctional acrylate monomer may be added to increase the strength of the insulating film. Further, inorganic or organic particles may be added as other ingredients to increase the strength of the insulating film or to improve the electrical characteristics of the insulating film. Meanwhile, the “insulating resin” in the invention means a resin that has insulation properties capable of being used in a known insulating film. Furthermore, even though being not an absolute insulator, the insulating resin can be used in the invention as long as the insulating resin is a resin having insulation properties depending on the purpose.

In the invention, the thickness of the insulating film is generally in the range of 1 μm to 10 mm, and it is preferable that the thickness of the insulating film be in the range of 10 to 1000 μm.

From the viewpoint of improving physical properties of a formed conductive layer (circuit), it is preferable that an average roughness (Rz), which is measured by a 10-point average height method according to JIS B 0601 (1994), the disclosure of which is incorporated by reference herein, of the insulating film made of an insulating resin be 3 μm or less, and it is more preferable that Rz be 1 μm or less. If the surface smoothness of the substrate is in the above-mentioned range, that is, if the substrate substantially does not have unevenness, it is preferable that the substrate be used to produce a printed wiring board having an extremely-fine circuit (for example, a circuit pattern of which values of line/space are 25/25 μm or less).

Further, from the viewpoint similar thereto, when wiring is formed on the substrate by using the laminated body according to the invention, it is also preferable that the smoothness of a substrate to be used be in the above-mentioned range.

### [Manufacture of Laminated Body for Producing Printed Wiring Board]

The laminated body for the printed wiring board according to the invention has a structure where the adhesive layer is formed on the insulating film for producing the printed wiring board. In this case, first, the (A) active species generating layer including the polymerization initiator is preferably formed on the surface of the insulating film for the printed wiring board by using an application method or a laminating method. Then, similarly to the above, the (B) polymer precursor layer is formed, and the (B) polymer precursor layer may be coated with a protective layer until a metal film is laminated.

The laminated body according to the invention has the following main characteristic. That is, the laminated body according to the invention includes an adhesive layer, which includes a polymer precursor layer and an active species generating layer, disposed on the surface of the insulating film for the printed wiring board, and the active species generating layer includes a polymerization initiator and an insulating resin, such as an epoxy resin, a polyimide resin, a liquid crystalline resin, or a polyarylene resin. Accordingly, by forming the adhesive layer on an arbitrary substrate or the surface of the wiring and applying energy, it is possible to form an insulating film for the printed wiring board having desired characteristics and a graft polymer generation region in which the graft polymer is directly bonded to the surface of the insulator layer. Since the graft polymer has excellent affinity to a conductive material and itself, it is possible to form the laminated body for producing the printed wiring board according to the invention by forming a metal film on the graft polymer. Since the adhesive layer is provided, it is possible to give excellent adhesion of the smooth conductive film (metal film) having high definition to the laminated body.

According to the invention, since a polymerization initiator is included in the adhesive layer as an active species generating composition, the adhesion between the insulating film for the printed wiring board and the graft polymer is further improved, thereby making the adhesion stronger.

The reason for this is not clear. However, it is deduced as follows: since the density of the surface graft is increased due to the use of the active species generating composition including a polymerization initiator, an interaction with the conductive material layer is increased. As a result, the adhesion is improved.

Further, this technology can be applied to a general insulating resin that is useful in a field of electronic materials, such as polyimide or epoxy resins.

### [Manufacture of Lamination Layer for Printed Wiring Board with Metal Film]

It is possible to form a graft polymer layer by applying energy to the laminated body where the (A) active species generating layer, and the (B) polymer precursor layer that includes a compound capable of forming a polymer compound by the reaction with the active species are formed on the surface of the insulating film for the printed wiring board by using an application method or a laminating method. For example, when the energy is light, an exposure source for applying energy is provided and exposure is directly performed on a desired region. Accordingly, the polymerizable compound contained in the (B) polymer precursor layer causes a strong chemical bond from an active spot generated by the initiator contained in the (A) active species generating layer, so that a graft polymer is generated in an exposed region. After that, by removing the unreacted (B) polymer precursor layer and adhering a conductive material to the graft polymer generated, it is possible to obtain the laminated body including the metal film for producing the printed wiring board.

### (Energy Application)

The formation of the graft polymer in the invention is performed by irradiating a radiant ray, such as heat or light. Heating by a heater or heating by infrared rays is used for the heat. Further, for example, a mercury lamp, a metal halide lamp, a xenon lamp, a chemical lamp, or a carbon-arc lamp is used as a light source. An electron beam, an X-ray, an ion beam, or a far-infrared ray is used as the radiant ray. Further, a g-ray, an i-ray, a Deep-UV ray, or a high-density energy beam (laser beam) may also be used.

If exposure is performed on the entire surface of the adhesive layer, a graft polymer is generated on the entire surface thereof. If pattern exposure is performed, a graft polymer is generated on the only exposed region so as to have the shape of a pattern.

If a conductive film is formed by applying a conductive material to the graft polymer, it is possible to obtain a conductive film that has excellent adhesion between the smooth insulating film for the printed wiring board and itself.

The thickness of the graft polymer layer formed as described above is preferably in the range of 0.05 to 5 μm.

The strong adhesion between the insulating film and the conductive material is achieved by the followings: 1. The strong adhesion between the insulating film and the active species generating layer, 2. The strong and high density bond between the active species generating layer and the graft polymer, and 3. The strong interactive bond between the generated graft polymer and the conductive material. To obtain this effect, it is important to select a compound that causes strong interaction or bond between the insulating film and the active species generating layer, or a compound that strongly interacts with the graft polymer and the conductive material, in addition to adding the polymerization initiator to the active species generating layer [(A) layer].

In this case, the thickness of a mixture layer where the graft polymer, the plating catalyst, deposited metal particles, conductive materials, and the metal film formed are mixed is preferably in the range of 10 nm to 2 μm, more preferably in the range of 20 nm to 1.5 μm, and still more preferably in the range of 30 nm to 1 μm. If the thickness of the mixture layer is set to the above-mentioned range, it is possible to obtain sufficient adhesion and excellent signal-transmitting characteristics. Accordingly, the occurrence of etching deficiencies can be suppressed, so that it is possible to form fine wiring.

A typical example of the method of adhering a conductive material to a graft polymer will be described below.

### [Method of Applying Conductive Material to Graft Polymer Formed on Surface of Insulator Layer]

Any one of (1) a process for adhering conductive particles to the generated graft polymer, (2) a process for applying a metal ion or a metal salt to the generated graft polymer and reducing the metal ion or a metal ion contained in metal salt to deposit a metal, (3) a process for applying an electroless plating catalyst or a precursor thereof to the generated graft polymer and performing electroless plating, and (4) a process for applying a conductive monomer and causing a polymerization reaction to form a conductive polymer layer may be preferably used as a process for applying conductivity to the graft polymer. Further, these (1) to (4) processes may be combined with each other, and another method such as electroplating may be additionally performed to further increase conductivity. Furthermore, a heating process may be further performed after a process for applying the conductive material.

In the invention, specifically, (2-1) a method of allowing a metal ion to be adsorbed to the graft polymer which is formed of a compound including a polar group (ionic group), or (2-2) a method of impregnating a metal salt or a solution including a metal salt into the graft polymer formed of a nitrogen-containing polymer, such as, polyvinyl pyrolidone, polyvinyl pyridine, or polyvinyl imidazole, which has high affinity to the metal salt, may be used as a method of performing (2) the process for applying a metal ion or a metal salt to the generated graft polymer and reducing the metal ion or the metal ion contained in the metal salt to deposit a metal, of the processes for applying the conductive material to the generated graft polymer to form the conductive film.

Further, a method including generating a graft polymer including a functional group interacting with an electroless plating catalyst or a precursor thereof, applying the electroless plating catalyst or the precursor thereof, and then performing electroless plating to form a metal thin film, is used as a method of performing (3) the process for applying an electroless plating catalyst or a precursor to the generated graft polymer and performing electroless plating. Even in this case, the graft polymer, which includes the functional group interacting with the electroless plating catalyst or a precursor thereof, is directly bonded to an insulating resin. Therefore, the formed metal thin film has conductivity, high strength, and abrasion resistance. Further, if electrolytic plating is further performed using, as an electrode, an electroless plating film, which can be obtained herein, it is possible to easily form a conductive film having a desired thickness.

Furthermore, according to the invention, specifically, any one of (1) a process for adhering conductive particles to the generated graft polymer (“conductive particle adhering process”), (2) a process for applying a metal ion or a metal salt to the generated graft polymer (“metal ion or metal salt applying process”), and then reducing the metal ion or a metal ion contained in the metal salt deposit metal (“metal (particle) film forming process”), (3) a process for applying an electroless plating catalyst or a precursor thereof to the generated graft polymer (“electroless plating catalyst applying process”) and performing electroless plating (“electroless plating process”), and (4) a process for applying a conductive monomer (“conductive monomer applying process”) and causing a polymerization reaction to form a conductive polymer layer (“conductive polymer forming process”) may be preferably used.

### (1) Process for Adhering Conductive Particles

In this process, conductive particles are directly adhered to the polar group of the graft polymer, and conductive particles to be exemplified below may be electrostatically and ionically adhered (adsorbed) to the polar group.

There are no particular limitations on conductive particles which can be used for the invention as long as the conductive particles have conductivity, and particles made of a known conductive material may be arbitrarily and selectively used. Preferable examples of conductive particles include metal particles such as Au, Ag, Pt, Cu, Rh, Pd, Al and Cr; oxide semiconductor particles such as In₂O₃, SnO₂, ZnO, CdO, TiO₂, CdIn₂O₄, Cd₂SnO₂, Zn₂SnO₄ and In₂O₃—ZnO; particles obtained by doping the impurities which can be applied thereto; spinel type compound particles such as MgInO and CaGaO; conductive nitride particles such as TiN, ZrN and HfN; conductive boride particles such as LaB; and conductive polymer particles as organic materials.

When a graft polymer includes an anionic polar group, a conductive film is formed by allowing conductive particles having a positive charge to be adsorbed to the graft polymer. Metal (oxide) particles having positive charges are used as cationic conductive particle used herein. Further, a conductive film is formed by allowing conductive particles having a negative charge to be adsorbed to a graft polymer including a cationic polar group.

It is preferable that the diameter of the conductive particle be in the range of 0.1 to 1000 nm, and it is more preferable that the diameter of the conductive particle be in the range of 1 to 100 nm. If the diameter of the conductive particle is smaller than 0.1 nm, conductivity that is caused by continuous contact of the particles tends to be decreased. If the diameter of the conductive particle is larger than 1000 nm, a contact area of the particle interacting with the functional group of which polarity is converted is decreased. For this reason, the strength of the conductive region tends to deteriorate.

### (2) Process for Applying Metal Ion or Metal Salt and Reducing Metal Ion or Metal Ion Contained in Metal Salt Deposit Metal

In an embodiment of method (2) of the conductive material adhering process according to the invention, a conductive pattern is formed by performing the process for applying a metal ion or a metal salt to the graft polymer (metal ion or metal salt applying process) and then reducing the metal ion or a metal ion contained in the metal salt to deposit a metal (“metal (particle) film forming process”). That is, according to the embodiment of method (2), metal ions such as hydrophilic groups included in the graft polymer or functional groups to which a metal salt is adhered allow the metal ions or the metal salt to be adhered (adsorbed) according to functions thereof, and the adsorbed metal ions are then reduced, so that a metal elementary substance are deposited in the graft polymer region. Depending on the form of deposition, a metal thin film may be formed or a layer with dispersed metal particles may be formed.

### (3) Process for Applying Electroless Plating Catalyst or Precursor and Performing Electroless Plating

In an embodiment of method (3) of the conductive film forming process according to the invention, the graft polymer includes a functional group interacting with the electroless plating catalyst or the precursor thereof, and a conductive pattern is formed by sequentially performing the process for applying an electroless plating catalyst or a precursor thereof to the generated graft polymer (“electroless plating catalyst applying process”) and performing electroless plating to form a metal thin film (“electroless plating process”). That is, according to the embodiment of method (3), the graft polymer, which includes the functional group (that is, polar group) interacting with the electroless plating catalyst or the precursor thereof, interacts with the electroless plating catalyst or the precursor thereof, and electroless plating is then performed, thereby forming a metal thin film.

As a result, a metal (particle) film is formed. When a metal thin film (continuous layer) is formed, a region having particularly high conductivity is formed. In this case, a heating process may be performed to improve conductivity after the adsorption of the particles.

“The process for applying a metal ion or a metal salt” and “the metal (particle) film forming process” in an embodiment of method (2) described above will be described in detail.

### <Process of Applying Metal Ion or Metal Salt>

### Metal Ion and Metal Salt

Next, the metal ion and the metal salt will be explained.

In the invention, there are no particular limitations on the metal salt, as long as the metal salt can be dissolved in a suitable solvent for applying to the graft polymer generation region and can be separated into a metal ion and a base (negative ion). Examples include M(NO₃)ₙ, MCln, M_{2/n}(SO₄), M_{3/n}(PO₄), wherein M represents an n-valent metal atom. The metal ion obtained by dissociating the above metal salt can be suitably used. Specific examples include an Ag ion, a Cu ion, an Al ion, a Ni ion, a Co ion, a Fe ion and a Pd ion. An Ag ion is preferably used for a conductive film, and a Co ion is preferably used for a magnetic film.

### [Method of Applying Metal Ions and Metal Salt]

In order to apply a metal ion or a metal salt to the graft polymer generation region, when the graft polymer includes an ionic group, a method of allowing metal ions to be adsorbed to the ionic group may be used. In this case, the metal salt is dissolved in a suitable solvent, the solution containing the dissociated metal ions may be applied on the insulating resin layer where a graft polymer exists, or an insulating resin layer including the graft polymer may be immersed in the solution. The metal ions can be ionically adsorbed to the ionic group by coming in contact with the solution including metal ions. From the viewpoint of sufficiently performing the adsorption, it is preferable that the metal ion concentration of the above-mentioned solution or the metal salt concentration be in the range of 1 to 50 mass %, and it is more preferable that the metal ion concentration of the above-mentioned solution or the metal salt concentration be in the range of 10 to 30 mass %. Further, it is preferable that contact time be in the range of about 10 seconds to 24 hours, and it is more preferable that contact time be in the range of about 1 to 180 minutes.

### <Metal (Particle) Film Forming Process>

### Reducing Agent

In the invention, there are no particular limitations on a reducing agent used for reducing the metal salt or the metal ion which adsorb the graft polymer or with which the graft polymer is impregnated, and forming a metal (particle) film, as long as a reducing agent can reduce the used metal salt compound, and has the physical properties for depositing a metal. Examples include hypophosphite, tetrahydro borate salt and hydrazine.

These reducing agents can be suitably selected depending on the relationship between the metal salt and the metal ion to be used. For example, when silver nitrate aqueous solution or the like is used as a metal salt aqueous solution supplying the metal ion and the metal salt, sodium tetrahydro borate may be suitably used. When an aqueous solution of palladium dichloride is used, hydrazine may be suitably used.

Examples of the methods for adding the above reducing agent include the following two methods. In a first method, after the metal ion or the metal salt is applied to the surface of the insulating resin layer on which the graft polymer exists, the surface is washed, and the excessive metal salt and metal ion are removed. The insulating resin layer provided with the surface is immersed in water such as ion exchanged water, and the reducing agent is added thereto. In a second method, a reducing agent aqueous solution having a predetermined concentration is directly coated or dropped on the surface of the insulating resin layer. It is preferable to use the reducing agent of an excessive amount of an equivalent or more to the metal ion, and more preferably 10 times equivalents or more.

Although the existence of the uniform metal (particle) film having high strength due to the addition of the reducing agent can be visually checked from the metal luster of the surface, the structure can be checked by observing the surface using a transmission electron microscope or an AFM (atomic force microscope). The film thickness of the metal (particle) film can be easily measured by a method for observing a cutting plane by a conventional means, for example, an electron microscope.

### [Relationship Between Polarity of Functional Group Included in Graft Polymer and Metal Ions or Metal Salt]

If the graft polymer includes a functional group having negative charges, a region where a metal elementary substance (metal thin film or metal particles) is deposited is formed by allowing metal ions having a positive charge to be adsorbed to the graft polymer and reducing the adsorbed metal ions. Further, if the graft polymer includes an anionic group, such as a carboxyl group, a sulfonic acid group, or a phosphonic acid group, as a hydrophilic functional group as described above, the graft polymer selectively has negative charges and a metal (particle) film region (for example, wiring) is formed by allowing metal ions having a positive charge to be adsorbed to the graft polymer and reducing the adsorbed metal ions.

Meanwhile, when a graft polymer chain includes a cationic group such as an ammonium group disclosed in JP-A No. 10-296895, the graft polymer selectively has positive charges and a metal (particle) film region (for example, wiring) is formed by allowing a solution containing a metal salt or a solution where a metal salt is dissolved to be impregnated into the graft polymer and reducing the metal ions contained in the solution or metal ions contained in the metal salt.

From the viewpoint of durability, it is preferable that such metal ion be bonded the maximum amount of the metal ion that can be applied (adsorbed) to the functional group capable of adsorbing metal ions.

A method of applying liquid, where metal ions or metal salt are dissolved, on the surface of the support, a method of immersing the surface of the support in the solution or dispersion liquid, or the like may be used as a method of applying metal ions to the functional group. Even in any case of application and immersion, the excessive amount of metal ions is supplied. In order to generate sufficient ionic bond or electronic interaction with the functional group, it is preferable that contact time between the solution or dispersion liquid and the surface of the support be in the range of 10 seconds to 24 hours, and it is more preferable that contact time be in the range of about 1 to 180 minutes.

Not only one kind of the metal ions but also a plurality of kinds of the metal ions can be used together if necessary. A plurality of materials may be mixed previously and then used so as to obtain the desired conductivity.

The conductive film produced in the invention is compactly dispersed in the surface graft film as determined through surface observation and section observation using SEM and AFM. The size of the metal particles produced is within a range of about 1 μm to about 1 nm.

When the metal particles adsorb densely in the conductive film prepared by the above method to form an appearance of a metal thin film, the conductive film may be used as it is. From the view point of ensuring efficient conductivity, it is more preferable to further subject the formed pattern to a heat treatment.

The heating temperature of the heat treatment process is preferably 100° C. or more, more preferably 150° C. or more, and particularly preferably about 200° C. The heating temperature is preferably 400° C. or less in consideration of the processing efficiency and the dimensional stability of the support insulating resin layer or the like. The heating time is preferably 10 minutes or more, and more preferably within the range of 30 minutes to 60 minutes. Although the operation mechanism due to the heat treatment is not clear, it appears that the conductivity can be improved since the metal particles closing fuse mutually.

“The process of applying an electroless plating catalyst or the like” and “the electroless plating process” in an embodiment of method (3) of the process of applying a conductive material according to the invention will be described in detail.

### <Process of Applying Electroless Plating Catalyst or the Like>

In the process, the electroless plating catalyst or the precursor thereof is applied to the graft polymer generated in the above surface graft process.

### [Electroless Plating Catalyst]

The electroless plating catalyst used in the process is mainly zero valence metal, and examples thereof include Pd, Ag, Cu, Ni, Al, Fe and Co. In the invention, particularly, Pd and Ag are preferable from the excellent handleability and the high catalyst power. For example, a technique for applying metal colloid in which charge is adjusted so as to interact with the interactive group in the interaction region to the interaction region is used as a technique for fixing a zero valence metal to an interaction region. Generally, the metal colloids can be produced by reducing the metal ion in a solution in which a surface-active agent having charges or a protecting agent having charge exist. The charge of the metal colloid can be adjusted by the surface-active agent or protecting agent used herein. Thus, the metal colloid (electroless plating catalyst) can be made to adhere to the graft polymer by interacting the metal colloid in which the charge is adjusted with the interactive group (polar group) contained in the graft polymer.

### [Electroless Plating Catalyst Precursor]

There are no particular limitations on the electroless plating catalyst precursor used in the process as long as the electroless plating catalyst precursor can become the electroless plating catalyst by a chemical reaction. The metal ion of the zero valence metal used in the above electroless plating catalyst may be mainly used. The metal ion which is the electroless plating catalyst precursor becomes the zero valence metal which is the electroless plating catalyst a reduction reaction. The metal ion which is the electroless plating catalyst precursor, after applied to the substrate in the process (b), may be changed to zero valence metal by the reduction reaction separately to be the electroless plating catalyst before the immersion to the electroless plating bath. Also, the metal ion may be immersed in the electroless plating bath in which the electroless plating catalyst precursor may be changed to the metal (electroless plating catalyst) by the reducing agent in the electroless plating bath.

In fact, the metal ion which is the electroless plating precursor is applied to the graft polymer in a state of the metal salt. There are no particular limitations on the metal salt used as long as the metal salt can be dissolved in a suitable solvent and can be dissociated into a metal ion and a base (negative ion). Examples include M(NO₃)ₙ, MCln, M_{2/n}(SO₄), M_{3/n}(PO₄), wherein M represents an n-valent metal atom. The metal ion obtained by dissociating the above metal salt can suitably be used. Specific examples include an Ag ion, a Cu ion, an Al ion, a nickel ion, a Co ion, a Fe ion and a Pd ion, and the Ag ion and the Pd ion are preferable in view of catalyst power.

Examples of the method for applying the metal colloid which is the electroless plating catalyst, or the metal salt which is the electroless plating precursor to the graft polymer include the following method. The metal colloid is dispersed in a suitable dispersion medium, or the metal salt is dissolved in a suitable solvent. A solution containing the metal ion dissociated is prepared. The solution may be coated on the surface of the insulating resin layer on which the graft polymer exists, or the laminated body having the insulating layer having the graft polymer may be immersed in the solution. The metal ion is made to adhere to the interactive group contained in the graft polymer by contacting the solution containing the metal ion using an ion-ion interaction or an electric dipole-ion interaction, or the interaction region can be impregnated with the metal ion. It is preferable that the metal ion concentration or metal salt concentration of the solution contacted is within the range of 0.01 to 50 mass % from the view point of the full adhesion and impregnation, and more preferably 0.1 to 30 mass %. The contact time is preferably about 1 minute to about 24 hours, and more preferably about 5 minutes to about 1 hour.

### <Electroless Plating Process>

In the process, a conductive film (metal film) is formed by carrying out electroless plating to the insulating resin layer to which the electroless plating catalyst is applied in the process of applying an electroless plating catalyst or the like. That is, a high-density conductive film (metal film) is formed on the graft polymer obtained by the process by carrying out electroless plating in the process. The formed conductive film (metal film) has excellent conductivity and adhesion.

### [Electroless Plating]

The electroless plating means an operation for depositing the metal by the chemical reaction using a solution in which the metal ion to be deposited as plating is dissolved.

In the electroless plating of the process, for example, the substrate to which the electroless plating catalyst obtained in the process for applying the electroless plating catalyst or the like is applied is washed with water, and the excessive electroless plating catalyst (metal) is removed. The substrate is then immersed in the electroless plating bath. A generally known electroless plating bath can be used as the electroless plating bath.

When the substrate to which the electroless plating catalyst precursor is applied is immersed in the electroless plating bath in the state that the electroless plating catalyst precursor is made to adhere to the graft polymer, or is impregnated with the graft polymer, after the substrate is washed with water and the excessive precursor is removed (metal salt or the like), the substrate is immersed in the electroless plating bath. In this case, the precursor is reduced in the electroless plating bath, and the electroless plating is then carried out. Similarly to the above, a generally known electroless plating bath can be used as the electroless plating bath used herein.

As the composition of the general electroless plating bath, (1) the metal ion for plating, (2) the reducing agent and (3) the additive agent (stabilizer) for enhancing the stability of the metal ion are mainly contained. In addition to these, known additives such as a stabilizer of the plating bath may be contained in the plating bath.

As the kind of the metal used for the electroless plating bath, copper, tin, lead, nickel, gold, palladium and rhodium are known, and copper and gold are particularly preferable from the view point of conductivity.

The reducing agents and the additives which may be suitably used with the above metals will be explained. For example, the electroless plating bath of copper contains Cu(SO₄)₂ as copper salt, HCOH as a reducing agent, and chelating agents such as EDTA and a roshell salt which are the stabilizer of copper ion as an additive agent. The plating bath used for the electroless plating of CoNiP contains cobalt sulfate and nickel sulfate as a metal salt; sodium hypophosphite as a reducing agent; and sodium malonate, sodium malate and sodium succinic acid as a complexing agent. The electroless plating bath of palladium contains (Pd (NH₃)₄) Cl₂ as the metal ion, NH₃, H₂NNH₂ as the reducing agent and EDTA as a stabilizing agent. Ingredients other than the above ingredient may be contained in these plating baths.

Although the film thickness of the conductive film (metal film) formed as described above can be controlled by the metal salt or metal ion concentration of the plating bath, the immersion time to the plating bath or the temperature of the plating bath or the like, the film thickness is preferably 0.1 μm or more from the view point of conductivity, and more preferably 3 μm or more. The immersion time to the plating bath is preferably within the range of about 1 minute to about 3 hours, and more preferably about 1 minute to about 1 hour.

In the conductive film (metal film) obtained as described above, the sectional observation according to SEM confirms that the electroless plating catalyst and the particles of the plating metal are tightly dispersed in the vicinity of the surface of the mixed layer and the comparatively larger particles are deposited thereon. Since the interface is in the hybrid state of the graft polymer and the particles, even if the difference of unevenness of the interface of the substrate (the organic ingredient) and the inorganic substance (the electroless plating catalyst or the plating metal) is 100 nm or less, the adhesion is excellent.

The mixed layer of the metal film formed by the generated graft polymer, the plating catalyst and the plating preferably has a thickness of 10 nm to 2 μm, more preferably 20 nm to 1.5 μm, and still more preferably 30 nm to 1 μm. When the thickness of the mixed layer is in the above range, it is possible to attain sufficient adhesion and favorable signal transmission properties, and to form fine wiring without etching deficiency concerns.

### <Electroplating Process>

An embodiment of method (3) of the conductive pattern forming method in accordance with the invention may include a process (electroplating process) of electroplating after the conductive film forming process.

After the conductive film forming process, the metal film (conductive film) formed by the conductive film forming process can be used as an electrode and electroplating can be further carried out in the electroplating process process. Thus, a metal film having an arbitrary thickness can be easily formed by using the metal film which is excellent in adhesion with the insulating resin layer as a base. The metal film having a thickness corresponding to the purpose can be formed by adding the process, and the conductive material obtained by this method may be suitably applied to various application.

As the method for electroplating of an embodiment of method (3), conventionally known methods can be used. Examples of the metals used for the electroplating of the process include copper, chromium, lead, nickel, gold, silver, tin, zinc. Copper, gold and silver are preferable from the view point of conductivity, and copper is more preferable.

The film thickness of the metal film obtained by electroplating is varied depending on the purpose, and the film thickness can be controlled by adjusting the metal concentration, immersion time or current density or the like contained in the plating bath. The film thickness in the case of using for a general electric wiring or the like is preferably 0.3 μm or more, and more preferably 3 μm or more from the view point of conductivity.

For example, the electroplating process in the invention may be carried out not only for the purpose of forming the patterned metal film having the thickness according to the purpose as described above, but also for the purpose of applying the obtained product to mounting of an IC or the like. In the latter case, the plating can be carried out to the conductive film or the metal pattern surface formed by copper or the like by using a material selected from the group consisting of nickel, palladium, gold, silver, tin, solder, rhodium, platinum and compounds thereof.

The “conductive monomer applying process” and the “conductive polymer layer forming process” of an embodiment of method (4) of the conductive material applying process according to the invention will be described below.

In the embodiment of method (4) of the conductive material adhering process, a conductive monomer to be described below is ionically adsorbed to an interactive group including the graft polymer, preferably, an ionic group, to allow a polymerization reaction to occur, so that a conductive polymer layer is formed. A conductive layer made of a conductive polymer is formed using the method.

In this case, the conductive layer made of the conductive polymer is formed by polymerizing a conductive monomer, which is ionically adsorbed in the interactive group of the graft polymer. Accordingly, the conductive layer has excellent adhesion to a substrate and excellent durability, and there is an advantage in that the thickness or conductivity of the conductive layer can be controlled by adjusting a polymerization condition such as a monomer feed rate.

The method of forming the conductive polymer layer is not particularly limited. However, from the viewpoint of forming a uniform thin film, it is preferable that the following method be used.

First, a substrate where a graft polymer is generated is immersed in a solution, which contains a polymerization catalyst such as potassium peroxydisulfate or iron (III) sulfate or a compound having a polymerization initiating ability. Further, while the solution is stirred, a monomer capable of forming a conductive polymer, for example, 3,4-ethylenedioxy thiophene is gently dropped into the solution. In this way, the interactive group (ionic group) in the graft polymer to which the polymerization catalyst or a polymerization initiating ability is applied and the monomer capable of forming a conductive polymer are adsorbed by mutual interaction. In addition, polymerization reaction between monomers proceeds, so that a very thin conductive polymer layer is formed on the graft polymer formed on a knit stitch surface of the insulating resin layer. Therefore, it is possible to obtain a uniform and thin conductive polymer layer.

As long as a polymer compound has conductivity of 10⁻⁶ s·cm⁻¹ or more, preferably, 10⁻¹ s·cm⁻¹ or more, any polymer compound may be used as a conductive polymer applied to the above-mentioned method. Specifically, for example, substituted and unsubstituted conductive polyaniline, polyparaphenylene, polyparaphenylene vinylene, polythiophene, polyfuran, polypyrrole, polyselenophene, polyisothianaphthene, polyphenylene sulfide, polyacethylene, polypyridylvinylene, polyazine, and the like may be used as the conductive polymer applied to the above-mentioned method. Only one of them may be used, and the combination of two or more thereof may be used depending on the purpose. Further, as long as a desired conductivity is obtained, a mixture of other polymers not having conductivity may be used and a copolymer of the monomer and copolymers not having conductivity may be used.

According to the invention, the conductive monomer itself electrostatically or polarly interacts with the interactive group of the graft polymer so as to be strongly adsorbed. Accordingly, strong interaction occurs between the conductive polymer layer formed by the polymerization of them and the graft polymer. As a result, even though being thin, the layer has sufficient strength against scratch or scrabble.

Further, if a material, where the conductive polymer is adsorbed to the interactive group of the graft polymer in a relationship between a positive ion and a negative ion, is selected, the interactive group is adsorbed as a counter anion of the conductive polymer and functions as a kind of dopant. Accordingly, it is possible to further improve the conductivity of the conductive polymer layer (conductivity manifestation layer). Specifically, for example, if a styrene sulfonic acid is selected as a polymerizable compound including an interactive group and thiophene is selected as a material of the conductive polymer, polythiophene that includes a sulfonic acid group (sulfo group) as a counter anion is generated on the interface between the graft polymer and the conductive polymer layer due to the interaction between the styrene sulfonic acid and the thiophene. The polythiophene functions as a dopant of the conductive polymer.

The thickness of the conductive polymer layer formed on the surface of the graft polymer is not particularly limited. However, it is preferable that the thickness of the conductive polymer layer be in the range of 0.01 to 10 μm, and it is more preferable that the thickness of the conductive polymer layer be in the range of 0.1 to 5 μm. If the thickness of the conductive polymer layer is in the above-mentioned range, it is possible to obtain sufficient conductivity and transparency. If the thickness of the conductive polymer layer is 0.01 μm or less, there is a concern that conductivity may become insufficient.

According to the invention, when a conductive layer is formed on the entire surface of the insulating layer by using the above-mentioned method, it is possible to form a conductive pattern material by etching the conductive layer.

### [Process for Forming Metal Pattern by Etching Metal Film]

A “subtractive method” or a “semiadditive method” is used as an etching method when a method of forming a metal pattern by etching a metal film, which is formed on the surface of the conductive material obtained by the invention, is performed.

### “Subtractive Method”

The subtractive method indicates the following method. (1) A resist layer is formed by coating or lamination on the metal film produced by the above technique. (2) The resist pattern of a conductor which should be left is formed by pattern exposure and development. (3) The unnecessary metal film is removed by etching. (4) The resist layer is stripped, and a metal pattern is formed. The film thickness of the metal film used for an embodiment of this method is preferably 5 μm or more, and more preferably within the range of 5 to 30 μm.

### (1) Resist Layer Coating Process

### Resist

As a photosensitive resist to be used, a photosetting negative resist or a photofusing positive resist dissolved by exposure can be used. As the photosensitive resist, (1) a photosensitive dry film resist (DFR), (2) a liquefied resist and (3) an ED (electrodeposition) resist can be used. These have characteristic respectively. (1) Since the photosensitive dry film resist (DFR) can be used in a dry method, the photosensitivity dry film resist can be simply treated. (2) Since the liquefied resist film can have a thin thickness as a resist, a pattern having sufficient resolution can be produced. (3) Since the ED (electrodeposition) resist can have a thin film thickness as a resist, a pattern having sufficient resolution can be produced. Also, the follow-up to the unevenness of the coating surface is excellent, and the adhesion is excellent. The resist to be used may be suitably selected by considering these features.

### Application Method

### 1. Photosensitive Dry Film

A photosensitive dry film generally has a sandwich structure, which is interposed between a polyester film and a polyethylene film, and is press-bonded by a hot calender roll while the polyethylene film is stripped by a laminator.

A prescription of a photosensitive dry film resist, a method of forming a photosensitive dry film resist, and a method of laminating a photosensitive dry film resist is described in detail in paragraph Nos. [0192] to [0372] in the specification of Japanese Patent Application No. 2005-103677, and the description therein can be applied to the invention.

### 2. Liquefied Resist

A spray coating method, a roll coating method, a curtain coating method, or a dip coating method may be used as an application method. It is preferable to use the roll coating method or the dip coating method, since both surfaces can be coated at the same time.

A liquefied resist is described in detail in paragraph Nos. [0199] to [0219] in the specification of Japanese Patent Application No. 2005-188722, and the description therein can be applied to the invention.

### 3. ED (Electrodeposition) Resist

The ED resist is colloids obtained by suspending particles made of photosensitive resist in water. Since the particles are charged, when voltage is applied to the conductor layer, the resist is deposited on the conductor layer by electrophoresis. The colloids are mutually connected on the conductor to be in a membrane state and can be coated.

### (2) Pattern Exposure Process

### “Exposure”

A substrate in which the resist film is provided on the upper part of the metal film is stuck with a mask film or a dry plate, and exposed with the light of the sensitization region of the resist used. In the case of using the film, the substrate is stuck by a vacuous baking flame and is exposed. An exposure source having a pattern width of about 100 μm can be used as a point light source. When a pattern having a width of 100 μm or less is formed, it is preferable to use a parallel light source.

### “Development”

Any developer may be used as long as it can dissolve a non-exposure part when the photosetting negative resist is used, or dissolve an exposure part when the photofusing positive resist is used. An organic solvent and an alkaline solution are mainly used as the developer, and an alkaline solution is used from environmental impact reduction in recent years.

### (3) Etching process

### “Etching”

The etching is a process for chemically dissolving the exposed metal layer which has no resist to form a conductive pattern. In an etching process, the etching solution is mainly sprayed from the upper and lower sides on a horizontal conveyor. As the etching solution, an oxidizing solution may be used to dissolve and oxidize a metal layer. As the etching solution, a ferric hydrochloric acid solution, a cupric chloride solution and alkali etchant may be used. Since the resist may be stripped by alkali, the ferric hydrochloric acid solution and the cupric chloride solution are mainly used.

Since the substrate interface is not made uneven in the method of the invention, the removal property of the conductive ingredient near the substrate interface is excellent. Since the graft polymer introducing the metal film on the substrate is connected with the substrate at the end of the polymer chain and has a structure having an extremely high motility, the etching solution can diffuse easily in the graft polymer layer in the etching process. In addition, the removal property of the metal component in the interface part between the substrate and the metal layer is excellent, the pattern having an excellent sharpness can be formed.

### (4) Resist Stripping Process

### “Stripping Process”

Since the etching resist is unnecessary after a metal (conductivity) pattern is completed by etching, a process for stripping the etching resist is required. The etching resist can be stripped by spraying a stripping solution. Although the stripping solution is different according to the kinds of the resist, a solvent for generally swelling the resist or a solution is sprayed by a spray. The resist is swelled and stripped.

### “Semiadditive Process”

In the semiadditive method, (1) a resist layer is coated on the metal film formed on the graft polymer. (2) A resist pattern of a conductor to be removed is formed by a pattern exposure and a development. (3) A metal film is formed on the non-pattern part of the resist by plating. (4) A photosensitive dry film resist (DFR) is stripped. (5) A metal film which is unnecessary is removed by etching. In these processes, technique similar to the “subtractive method” can be used. The electroless plating and electroplating explained above as the plating technique can be used. The film thickness of the metal film used is preferably about 1 to about 3 μm in order to complete the etching process in a short time. The electrolytic plating and the electroless plating may be further carried out to the formed metal pattern.

It is possible to obtain a conductive pattern material, which uses the conductive material obtained by the invention, by using the etching method. Since a metal film having high adhesion is formed on a smooth substrate in the conductive material obtained by the invention, a fine metal pattern having high adhesion is formed on the smooth substrate by etching. For this reason, the conductive material obtained by the invention is useful to form various electric circuits.

As described above, it is possible to easily form a printed wiring board having excellent characteristics on the surface of an arbitrary solid by using the laminated body according to the invention. That is, without making the surface of the insulating resin material layer, which is used as a substrate in a field of a printed wiring board and has heat resistance and a low dielectric constant, such as an epoxy resin, a polyimide resin, a liquid crystalline resin, or a polyarylene resin, rough, it is possible to easily obtain a metal film material having high adhesive strength, for example, a copper clad laminated plate.

If the conductive material such as a copper clad laminated plate, which is obtained by the manufacturing method according to the invention, is used, it is possible to form copper wiring having fine patterns of 20 micron or less and high adhesive strength, which has difficulty in being achieved in the related art, by, for example, a known etching treatment.

Further, it is also possible to easily produce a multilayered wiring board by laminating the laminated body on the surface of the insulating film where wiring has been already formed. A multilayered wiring board is described in detail in paragraph Nos. [0107] to in the specification of Japanese Patent Application No. 2005-322867, and the process described therein can be applied to the laminated body of the invention.

The laminated body for producing a printed wiring board according to the invention includes an adhesive layer, which can exhibit excellent adhesiveness even if a resin having heat resistance and a low dielectric constant such as an epoxy resin, a polyimide resin, a liquid crystalline resin, or a polyarylene resin is used as a material of the insulating film. For this reason, the laminated body is useful to form a flexible wiring board or a printed wiring board, which has high adhesion strength, without making the surface of the insulating film rough. The laminated body for producing a printing wiring board according to the invention can be applied to a method of manufacturing a printed wiring board that is easy and is suitable for high density mounting.

### EXAMPLES

The present invention will be described in detail below with reference to specific examples, but is not limited to the specific examples.

### Examples 1 to 5

### Formation of Adhesive Layer on Surface of Support

A polyethylene terephthalate film having a thickness of 16 μm, on which a surface treatment or a pretreatment is not performed, was prepared, and was used as a support for forming an adhesive layer.

A polymer precursor composition 1 having the following composition, which contains a polymer (polymer including a polymerizable group on a side chain: P-1, which is obtained by a synthesis example to be described below) including an acrylic group as a polymerizable compound and a carboxyl group as an interactive group, was applied on the surface of the support by using a rod bar #6, and dried at 100° C. for one minute, thereby forming a polymer precursor layer [(B) layer]. The thickness of the polymer precursor layer was set in the range of 0.2 to 1.5 μm.

### (Polymer Precursor Composition Embrocation 1)

| | |
|---|---|
| Hydrophilic polymer (P-1) having a polymerizable | 3.1 g |
| group on a side chain | |
| Water | 24.6 g |
| 1-methoxy-2-propanol | 12.3 g |

The viscosity of the polymer precursor composition coating liquid 1 was measured at 28° C., and a value of the viscosity was 16 cps.

### Synthesis Example

### Synthesis of Polymer P-1 Having Double Bond

60 g of polyacrylic acid (average molecular weight 25000, available from Wako Pure Chemical Industries, Ltd.) and 1.38 g (0.0125 mol) of hydroquinone (available from Wako Pure Chemical Industries, Ltd.) were put in a three-necked flask, which had a volume of 1 L and was provided on a cooling pipe, and 700 g of N,N-dimethyl acetamide (DMAc, Wako Pure Chemical Industries, Ltd.) was added thereto and stirred at a room temperature, and therefore, a uniform solution was obtained. While the solution was stirred, 64.6 g (0.416 mol) of 2-methacryloyloxyethyl isocyanate (trade name: KARENZ MOI, available from Showa Denko K. K.) was dropped. Subsequently, 0.79 g (1.25×10⁻³ mol) of di-n-butyltin dilaurate (available from Tokyo Chemical Industry Co., Ltd.) suspended in 30 g of DMAc was dropped. While being stirred, the solution was heated by a water bath, the temperature of which is 65° C. The heating was stopped after 5 hours, and the solution was naturally-cooled to a room temperature. The acid value of the reaction solution was 7.105 mmol/g and the solid content thereof was 11.83%.

300 g of the reaction solution was put in a beaker, and was then cooled by an ice bath to 5° C. While the reaction solution was stirred, 41.2 ml of a sodium hydrateaqueous (4N) solution was dropped for about one hour. During the dropping, the temperature of the reaction solution was in the range of 5 to 11° C. After the dropping, the reaction solution was stirred at a room temperature for 10 minutes, and solid matter was removed by suctioning filtration, thereby obtaining a brown solution. The solution was reprecipitated by 3 liters of ethyl acetate and was filtered to obtain the deposited solid. The solid was reslurried all night by 3 liters of aceton. The solid was taken out by filtration and then vacuum-dried for 10 hours, thereby obtaining light brown powder P-1. 1 g of the polymer was dissolved in a mixture solvent of 2 g of water and 1 g of acetonitrile. A pH of the solution was 5.56, and the viscosity thereof was 5.74 cps. The viscosity was measured at 28° C. using a viscometer (trade name: RE80, manufactured by Toki Sangyo Co. Ltd.) and a rotor (trade name: 30XR14). Further, the molecular weight by GPC was 30000.

### Specific Example 1

### Formation of Active Species Generating Layer 1

While 20 parts by weight of a bisphenol A epoxy resin (epoxy equivalent 185, trade name: EPIKOTE 828, manufactured by Yuka-Shell Epoxy Co. Ltd.), 45 parts by weight of a cresol novolac epoxy resin (epoxy equivalent 215, trade name: EPICLON N-673, manufactured by Dainippon Ink And Chemicals, Inc.), and 30 parts by weight of a phenol novolac resin (phenolic hydroxyl group equivalent 105, trade name: PHENOLITE, manufactured by Dainippon Ink And Chemicals, Inc.) were heated and dissolved in 20 parts by weight of ethyldiglycol acetate and 20 parts by weight of solvent naphtha, while being stirred. Then, the mixture was cooled to a room temperature. After that, 30 parts by weight of cyclohexanone varnish (trade name: YL6747H30, manufactured by Yuka-Shell Epoxy Co. Ltd., nonvolatile ingredient 30 mass %, and weight average molecular weight 47000) of a phenoxy resin formed of the EPIKOTE 828 and the bisphenol S, 0.8 parts by weight of 2-phenyl-4,5-bis(hydroxymethyl)imidazole, 2 parts by weight of fine grinding silica, and 0.5 parts by weight of a silicon-based anti-foaming agent were added to the mixture, thereby producing epoxy resin varnish.

Further, 10 parts by weight of a polymerization initiating polymer P, which was synthesized by the following method, was added to, and dissolved in the mixture while the mixture was stirred, thereby producing epoxy resin varnish. The epoxy resin varnish was applied on the polymer precursor layer by a die coater so that the epoxy resin varnish had a thickness of 70 μm after drying. Then, the epoxy resin varnish was dried at a temperature of 80 to 120° C. so as to form an active species generating layer 1 [(A) layer]. Thereby, an adhesive layer having a double layer structure, which included a (B) layer and an (A) layer, was formed on the support. The viscosity of the coating liquid 1 for the active species generating layer was measured in a manner similar to a coating liquid for the polymer precursor layer, and was 580 cps.

In addition, a polypropylene film having a thickness of 20 μm was provided as a protective layer. Accordingly, a laminated body 1 in which an active species generating layer and the polymer precursor layer were formed on the support by application and which was covered by a protective layer, was obtained.

### (Synthesis of Polymerization Initiating Polymer P)

30 g of propylene glycol monomethyl ether (MFG) was put in a three-necked flask having a volume of 300 ml, and was then heated up to 75° C. A solution, which was formed of 8.1 g of [2-(acryloyloxy)ethyl] (4-benzoylbenzyl)dimethyl ammonium bromide, 9.9 g of 2-hydroxyethylmethaacrylate 9.9 g, 13.5 g of isopropylmethaacrylate, 0.43 g of dimethyl-2,2′-azobis(2-methyl propionate), and 30 g of MFG, was dropped into the mixture for 2.5 hours. After that, reaction temperature was raised up to 80° C. and a reaction was further performed for 2 hours, so that a polymer P including a polymerization initiating group was obtained.

### Specific Example 2

### Formation of Active Species Generating Layer 2

5 g of a liquid bisphenol A epoxy resin (epoxy equivalent 176, trade name: EPIKOTE 825, manufactured by Japan Epoxy Resins Co., Ltd.), 2 g of MEK varnish of a phenol novolac resin having triazine structure (trade name: PHENOLITE LA-7052, manufactured by Dainippon Ink And Chemicals, Inc., nonvolatile ingredients 62%, phenolic hydroxyl group equivalent of nonvolatile ingredients 120), 10.7 g of phenoxy resin MEK varnish (trade name: YP-50EK35 manufactured by Tohto Kasei Co., Ltd., nonvolatile ingredient 35%), 2.3 g of 1-[4-(2-hydroxyethoxy)phenyl]-2-hydroxy-2-methylpropan-1-one used as a polymerization initiator, 5.3 g of MEK, and 0.053 g of 2-ethyl-4-methylimidazole were mixed and stirred so as to be completely dissolved, thereby producing a varnish-like epoxy resin composition. The epoxy resin varnish was applied on the polymer precursor layer [(B) layer] by a die coater so that the epoxy resin varnish had a thickness of 90 μm after drying. Then, the epoxy resin varnish was dried at a temperature of 80 to 120° C. so as to form an active species generating layer 2. In this case, the viscosity of the coating liquid 2 for the active species generating layer was measured in a manner similar to a coating liquid for the polymer precursor layer, and was 605 cps.

In addition, a polypropylene film having a thickness of 20 μm was provided as a protective layer, and thereby, a laminated body 2 in which the active species generating layer 2 and the polymer precursor layer were formed on the support by application, and which was covered with the protective layer, was obtained.

### Specific Example 3

### Formation of Active Species Generating Layer 3

70 parts by weight of phthalic anhydride modified novolac epoxy acrylate having an acid value of 73 (trade name: PCR-1050, manufactured by Nippon Kayaku Co., Ltd. was used), 20 parts by weight of acrylonitrile butadiene rubber (trade name: PNR-1H, manufactured by Japan Synthetic Rubber Co., Ltd. was used), 3 parts by weight of an alkyl phenol resin (trade name: HITANOL 2400, manufactured by Hitachi Chemical Co., Ltd. was used), 7 parts by weight of a radical photopolymerization initiator (trade name: IRGACURE 651, manufactured by Ciba Specialty Chemicals, was used), 10 parts by weight of aluminum hydroxide (trade name: HIGILITE H-42M manufactured by Showa Denko K. K. was used), and 30 parts by weight of methyl ethyl ketone were mixed, so that a material for forming an insulating film was prepared.

The material resin varnish for forming the insulating film was applied on a polymer precursor layer of the polymer precursor layer film by a die coater so that the material resin varnish had a thickness of 50 μm after drying. Then, the material resin varnish was dried at a temperature of 80 to 120° C. so as to form an active species generating layer 3. The viscosity of the coating liquid 3 for the active species generating layer was measured in a manner similar to a coating liquid for the polymer precursor layer, and was 1200 cps.

In addition, a polypropylene film having a thickness of 20 μm was provided as a protective layer, and thereby a laminated body 3 in which the active species generating layer 3 and the polymer precursor layer were formed on the support by application, and which is covered with the protective layer, was obtained.

### Specific Example 4

### Formation of Active Species Generating Layer 4

50 g of a polyphenylene ether resin (trade name: PKN4752, manufactured by GE Plastics Japan Ltd.), 100 g of 2,2-bis(4-cyanatophenyl)propane (trade name: AROCYB-10, manufactured by Asahi Kasei Epoxy Co., Ltd.), 28.1 g of 9,10-dihydro-9-oxa-10-phosphaphenanthrene-10-oxide (trade name: HCA-HQ, manufactured by Sanko Co., Ltd.), 0.1 g of a 17% toluene-diluted solution of manganese naphthenate (Mn content=6% by weight, manufactured by Nihon Kagaku Sangyo Co., Ltd.), 88.3 g of 2,2-bis(4-glycidyl phenyl)propane (trade name: DER331L, manufactured by Dow Chemical Company), and 3.3 g of 1-[4-(2-hydroxyethoxy)phenyl]-2-hydroxy-2-methylpropan-1-one used as a polymerization initiator were added to 183 g of toluene, and heated and dissolved at 80° C., thereby preparing the coating liquid. The material resin coating liquid for forming the insulating film was applied on the polymer precursor layer by a die coater so that the material resin coating liquid had a thickness of 50 μm after drying. Then, the material resin coating liquid was dried at a temperature of 80 to 120° C. so as to form an active species generating layer 4. The viscosity of the coating liquid 4 for the active species generating layer was measured in a manner similar to a coating liquid for the polymer precursor layer, and was 377 cps.

In addition, a polypropylene film having a thickness of 20 μm was provided as a protective layer, and thereby a laminated body 4 in which the active species generating layer 4 and the polymer precursor layer were formed on the support by application, and which is covered with the protective layer, was obtained.

### Specific Example 5

### Active Species Generating Layer 5

70 parts by weight of a 25%-acrylic compound of a cresol novolac epoxy resin (manufactured by Nippon Kayaku Co., Ltd., molecular weight 2500) dissolved in diethylene glycol dimethyl ether, 30 parts by weight of polyether sulfone, 4 parts by weight of an imidazole-based hardening agent (trade name: 2E4MZ-CN, manufactured by Shikoku Chemicals Corporation), 10 parts by weight of caprolactone tris(acryloyloxy)isocyanurate (trade name: ARONIX M325, manufactured by Toagosei Co., Ltd.), 5 parts by weight of benzophenone (manufactured by Tokyo Chemical Industry Co., Ltd.), 0.5 parts by weight of Michler's ketone (manufactured by Tokyo Chemical Industry Co., Ltd.), and 20 parts by weight of epoxy resin particles having an average diameter of 0.5 μm were mixed. The mixed material resin coating liquid for forming the insulating film was applied on the polymer precursor layer by a die coater so that the material resin coating liquid had a thickness of 70 μm after drying. Then, the material resin coating liquid was dried at a temperature of 80 to 120° C. so as to form an active species generating layer 5. The viscosity of the coating liquid 5 for the active species generating layer was measured in a manner similar to a coating liquid for the polymer precursor layer, and was 780 cps.

In addition, a polypropylene film having a thickness of 20 μm was provided as a protective layer, and thereby a laminated body 5 in which the active species generating layer 5 and the polymer precursor layer were formed on the support by application, and which is covered with the protective layer was obtained.

### (Production of Printed Wiring Board Using Laminated Body)

### (1-1) Fixing of Laminated Body for the Printed Wiring Board to Substrate

The laminated bodies 1 to 5 obtained as described above were used. Each of the laminated bodies from which a protective layer had been stripped was provided on the substrate (patterned glass epoxy inner layer-circuit board (thickness of a conductor: 18 μm): corresponds to an insulating film for a printed wiring board) where wiring is to be formed so that the active species generating layer [(A) layer] was disposed on the surface of the substrate. Then, the laminated body was adhered on the substrate at a pressure of 0.2 Mpa and a temperature of 100 to 110° C. by a vacuum laminator. Thereby, each of adhesive layers 1 to 5 was formed on the surface of the insulating film for the printed wiring board.

### (1-2) Exposure (Formation of Graft Polymer)

Next, the supports of the laminated bodies 1 to 5 were stripped. Then, entire surface exposure and cleaning treatment were performed on the resultant products by the following method, so that surface graft pattern materials 1 to 5 including polymer grafts formed on the active species generating layers 1 to 5 were obtained. The thicknesses of the surface graft layers were 450 nm, 600 nm, 500 nm, 900 nm, and 700 nm, respectively.

Exposure was performed using an exposure device: ultraviolet exposure device (trade name: UVX-02516SILP01, manufactured by Ushio, Inc.) at a room temperature for 45 seconds. After exposure, the products were sufficiently cleaned with pure water.

### (1-3) Adhesion of Conductive Material and Confirmation of Adhesion

A conductive material was applied to the surface graft pattern materials 1 to 5 of the invention, which were obtained as described above, by using the method shown in Table 1, of the following two methods, so that printed wiring boards of Examples 1 to 5 were obtained.

### Conductivity Applying Method A: Implementation of Electroless Plating and Electrolytic Plating Processes

The surface graft materials 1 to 3 were immersed in an aqueous solution of 0.1 mass % of silver nitrate (manufactured by Wako Pure Chemical Industries, Ltd.) for one hour, and then cleaned with distilled water. After that, the surface graft materials were immersed in an electroless plating bath having the following composition for 10 minutes and then electroplated in an electroplating bath having the following composition for 20 minutes, so that conductive pattern materials of the examples 2 to 4 were produced.

<Ingredients of Electroless Plating Bath>

| | | |
|---|---|---|
| Copper sulfate | 0.3 | g |
| Tartaric acid NaK | 1.75 | g |
| Sodium hydrate | 0.75 | g |
| Formaldehyde | 0.2 | g |
| Water | 47 | g |

<Composition of Electroplating Bath>

| | | |
|---|---|---|
| Copper sulfate | 38 | g |
| Sulfuric acid | 95 | g |
| Hydrochloric acid | 1 | mL |
| Copper sulphate gloss agent | 3 | mL |
| (trade name: COPPER GRIM PCM; | | |
| manufactured by Meltex, Inc.) | | |
| Water | 500 | g |

### Conductivity Applying Method B: Implementation of Adhering Conductive Particles and Electroless Plating Process

The formed graft pattern materials 4 to 5 were immersed for one hour in a liquid where Ag particles having a positive charge, which were formed by the following method, were dispersed, and then cleaned with distilled water. After that, the copper clad laminated plates [conductive materials] of examples 4 and 5 were produced by using the same plating method as the conductivity applying method A.

### <Synthesis Technique of Ag Particles Having Positive Charge>

3 g of bis(1,1-trimethyl ammonium decanoyl aminoethyl)disulfide was added to 50 ml of an ethanol solution of silver perchlorate (5 mM). Then, while the mixture was intensely stirred, 30 ml of a sodium borohydride solution (0.4 M) was gently dropped into the mixture so as to reduce ions, thereby obtaining a dispersion where silver particles covered with quaternary ammonium were dispersed.

### [Evaluation of Conductive Pattern Materials]

### (Surface Unevenness)

The surface unevenness of the obtained conductive material was measured by a desk-top scanning probe microscope (trade name: NANOPICS 1000, available from Seiko Instruments Inc. A DMF cantilever was used). Results of the measurement were shown in the following Table 1.

### (Measurement of Thickness of Metal Film)

The thickness of a metal film was measured using a DMF cantilever.

### (Evaluation of Adhesion Strength)

A copper plate (thickness: 50 μm) was adhered to the surface of the conductive material having a metal film by using an epoxy-based adhesive (trade name: ARALDITE, manufactured by Ciba Specialty Chemicals), and dried at 140° C. for four hours. Then, a 90 degree-stripping test was performed in accordance with JIS C6481, the disclosure of which is incorporated by reference herein. A tensile tester (trade name: AGS-J, manufactured by Shimadzu Corporation) was used as a stripping apparatus. Results of the test are shown in the following Table 1.

TABLE 1

| | | | | Unevenness | |
|---|---|---|---|---|---|
| | | | | (Rz: nm) on | |
| | | Surface | Conductivity | surface of | Adhesion |
| | Laminated | graft | applying | conductive | strength |
| | body | material | method | material | (kN/m) |
| Example 1 | 1 | 1 | A | 410 | 0.7 |
| Example 2 | 2 | 2 | A | 700 | 0.8 |
| Example 3 | 3 | 3 | A | 720 | 0.8 |
| Example 4 | 4 | 4 | B | 450 | 0.7 |
| Example 5 | 5 | 5 | B | 550 | 0.8 |

As shown in Table 1, it can be seen that, in each of the printed wiring boards obtained by the method according to the invention, a metal film, having a sufficient thickness and excellent adhesion between the substrate and itself, was formed on a surface of the insulating film for a printed wiring board, the surface of the insulating film having little unevenness and being smooth.

### 5. Formation of Patterns

Fine wiring was formed using conductive materials (copper substrates) obtained in Examples 1 to 5.

A photocurable photosensitive dry film (manufactured by Fuji Photo Film Co., Ltd.) was laminated on the surfaces of the conductive materials (examples 1 to 5), and ultraviolet exposure was performed on the obtained product through a mask film having desired conductive circuit patterns (portions having metal patterns corresponding to openings and portions not having metal patterns corresponding to a mask), so that images were exposed. Then, the resulting product was developed. After that, the metal film (copper thin film) corresponding to the portions not having a resist was removed by using a cupric chloride etchant. Subsequently, fine copper patterns were obtained by stripping the dry film. The shape of the patterns was measured.

The formed conductive patterns were evaluated using the following parameters.

### (Pattern Formability)

Line width was measured using an optical microscope (trade name: OPTI PHOTO-2, manufactured by Nikon Corporation). Results of the measurement were shown in the following Table 2.

### (Surface Unevenness)

The surface unevenness of the obtained conductive material was measured by a desk-top scanning probe microscope (trade name: NANOPICS 1000, available from Seiko Instruments Inc. A DMF cantilever was used). Results of the measurement were shown in the following Table 2.

### (Evaluation of Adhesion Strength)

A copper plate (thickness: 50 μm) was adhered to the surface of the metal pattern (width: 5 mm) by using an epoxy-based adhesive (trade name: ARALDITE, manufactured by Ciba Specialty Chemicals), and dried at 140° C. for four hours. Then, a 90 degree-stripping test was performed in accordance with JIS C6481, the disclosure of which is incorporated by reference herein. A tensile tester (trade name: AGS-J, manufactured by Shimadzu Corporation) was used as a stripping apparatus. Results of the test were shown in the following Table 2.

TABLE 2

| | | Unevenness | |
|---|---|---|---|
| | | (Rz: nm) on surface of | Adhesion strength |
| | Line/space (μm) | substrate | (kN/m) |
| Example 1 | 20/20 | 420 | 0.68 |
| Example 2 | 15/18 | 650 | 0.68 |
| Example 3 | 25/25 | 750 | 0.8 |
| Example 4 | 21/22 | 430 | 0.85 |
| Example 5 | 15/15 | 630 | 0.7 |

As shown in Table 2, it can be seen that, when the conductive materials according to the invention are used for forming conductive patterns, it is possible to form fine wiring having excellent adhesion between the substrate and itself, on a smooth insulating film of a substrate with little unevenness.

According to the invention, it is possible to provide a laminated body for producing a printed wiring board where a conductive layer that has excellent adhesion between the insulating film and itself and has high definition can be easily formed on the surface of a chosen solid body. Further, it is possible to provide a method of producing on a substrate a printed wiring board, which has high-definition wiring with excellent adhesion, by using the laminated body for producing a printed wiring board of the invention.

Exemplary embodiments of the present invention will be listed as follows. However, the invention is not limited to the following exemplary embodiments.

[1] A laminated body for producing a printed wiring board, the laminated body comprising:

an adhesive layer that is provided between an insulating film for a printed wiring board and a metal film for forming wiring, the adhesive layer comprising an active species generating composition that is capable of generating an active species having reactivity by energy application, and a polymer precursor composition that includes a compound capable of forming a polymer compound by reaction with the active species generating composition.

[2] The laminated body for producing a printed wiring board as described in [1], wherein: the adhesive layer has a layered structure including an active species generating layer that is capable of generating the active species by energy application and a polymer precursor layer that includes the compound capable of forming a polymer compound by reaction with the active species generating layer.

[3] A method of producing a printed wiring board, the method comprising:

applying, on a surface of an insulating film for a printed wiring board, a coating liquid for forming an adhesive layer, the coating liquid comprising an active species generating composition that is capable of generating an active species having reactivity by energy application and comprising a polymer precursor composition that includes a compound capable of forming a polymer compound by reaction with the active species generating composition;

drying the coating liquid to form an adhesive layer; and

forming a metal film capable of forming wiring, on a surface of the adhesive layer.

[4] A method of producing a printed wiring board, the method comprising:

forming an adhesive layer by sequentially applying on a surface of an insulating film for a printed wiring board an active species generating layer coating liquid that is capable of generating an active species having reactivity by energy application, and a polymer precursor layer coating liquid that includes a compound capable of forming a polymer compound by the reaction with the active species generating layer coating liquid; and

forming a metal film capable of forming wiring, on a surface of the adhesive layer.

[5] The method of producing a printed wiring board as described in [4], wherein:

the viscosity of the active species generating layer coating liquid is in the range of 5 to 5000 cps.

[6] The method of producing a printed wiring board as described in [4], wherein:

the viscosity of the polymer precursor layer coating liquid is in the range of 1 to 2000 cps.

[7] The method of producing a printed wiring board as described in any one of [3] to [6], wherein:

the metal film is formed using an electroless plating method, an electroplating method, or a combination thereof.

[8] A method of producing a printed wiring board, the method comprising:

forming an adhesive layer by sequentially laminating on a surface of an insulating film for a printed wiring board an active species generating layer made of an active species generating composition that is capable of generating an active species having reactivity by energy application, and a reactive polymer precursor layer that includes a compound capable of forming a polymer compound by reaction with the active species generating layer; and

forming on a surface of the adhesive layer a metal film capable of forming wiring.

[9] The method of producing a printed wiring board as described in any one of [3] to [8], wherein the metal film is formed: by interacting, on the surface of the insulating film for a printed wiring board, a plating catalyst, deposited metal particles, or a conductive material with a graft polymer that has been made from an active species generating layer made with an active species generating composition that is capable of generating an active species having reactivity by energy application and a polymer compound that is formed by reaction with the active species generating layer; and by an electroless plating method, an electroplating method, or a combination thereof using the plating catalyst, the deposited metal particles, or the conductive material.

[10] The method of producing a printed wiring board as described in any one of [3] to [8], wherein a mixture layer is formed on the surface of the insulating film for producing the printed wiring board, the mixture layer being formed including: a generated graft polymer; a plating catalyst, deposited metal particles or a conductive material; and the formed metal film.

[11] The method of producing a printed wiring board as described in [10], wherein:

the thickness of the mixture layer is in the range of 10 nm to 2 μm.

[12] A method of producing a printed wiring board, the method comprising:

placing a laminated body for producing a printed wiring board described in [1] or [2], on or above a substrate; and then

forming a polymer generation region by applying energy and generating a polymer compound which is directly bonded to the active species generating layer, improving adhesiveness between the substrate and the metal film by the generated polymer compound.

All publications, patent applications, and technical standards mentioned in this specification are herein incorporated by reference to the same extent as if each individual publication, patent application, or technical standard was specifically and individually indicated to be incorporated by reference.

What is claimed is:

1. A laminated body for producing a printed wiring board, the laminated body comprising:
an adhesive layer that is provided between an insulating film for a printed wiring board and a metal film for forming wiring, the adhesive layer comprising an active species generating composition that is capable of generating an active species having reactivity by energy application, and a polymer precursor composition that includes a compound capable of forming a polymer compound by reaction with the active species generating composition.

2. The laminated body for producing a printed wiring board according to claim 1, wherein:
the adhesive layer has a layered structure including an active species generating layer that is capable of generating the active species by energy application, and a polymer precursor layer that includes the compound capable of forming a polymer compound by reaction with the active species generating layer.

3. A method of producing a printed wiring board, the method comprising:
applying, on a surface of an insulating film for a printed wiring board, a coating liquid for forming an adhesive layer, the coating liquid comprising an active species generating composition that is capable of generating an active species having reactivity by energy application and comprising a polymer precursor composition that includes a compound capable of forming a polymer compound by reaction with the active species generating composition;
drying the coating liquid to form an adhesive layer; and
forming a metal film capable of forming wiring, on a surface of the adhesive layer.

4. A method of producing a printed wiring board, the method comprising:
forming an adhesive layer by sequentially applying on a surface of an insulating film for a printed wiring board an active species generating layer coating liquid that is capable of generating an active species having reactivity by energy application, and a polymer precursor layer coating liquid that includes a compound capable of forming a polymer compound by reaction with the active species generating layer coating liquid; and
forming a metal film capable of forming wiring, on a surface of the adhesive layer.

5. The method of producing a printed wiring board according to claim 4, wherein:
the viscosity of the active species generating layer coating liquid is in the range of 5 to 5000 cps.

6. The method of producing a printed wiring board according to claim 4, wherein:
the viscosity of the polymer precursor layer coating liquid is in the range of 1 to 2000 cps.

7. The method of producing a printed wiring board according to claim 3, wherein:
the metal film is formed using an electroless plating method, an electroplating method, or a combination thereof.

8. A method of producing a printed wiring board, the method comprising:
forming an adhesive layer by sequentially laminating on a surface of an insulating film for a printed wiring board an active species generating layer made of an active species generating composition that is capable of generating an active species having reactivity by energy application, and a reactive polymer precursor layer that includes a compound capable of forming a polymer compound by reaction with the active species generating layer; and
forming on a surface of the adhesive layer a metal film capable of forming wiring.

9. The method of producing a printed wiring board according to claim 3, wherein the metal film is formed: by interacting, on the surface of the insulating film for a printed wiring board, a plating catalyst, deposited metal particles, or a conductive material with a graft polymer that has been made from an active species generating layer made with an active species generating composition that is capable of generating an active species having reactivity by energy application and a polymer compound that is formed by reaction with the active species generating layer; and by an electroless plating method, an electroplating method, or a combination thereof, using the plating catalyst, the deposited metal particles, or the conductive material.

10. The method of producing a printed wiring board according to claim 3, wherein a mixture layer is formed on the surface of the insulating film for producing the printed wiring board, the mixture layer being formed including: a generated graft polymer; a plating catalyst, deposited metal particles or a conductive material; and the formed metal film.

11. The method of producing a printed wiring board according to claim 10, wherein:
the thickness of the mixture layer is in the range of 10 nm to 2 μm.

12. A method of producing a printed wiring board, the method comprising:
placing a laminated body for producing a printed wiring board according to claim 1, on or above a substrate; and then
forming a polymer generation region by applying energy and generating a polymer compound which is directly bonded to the active species generating layer, improving adhesiveness between the substrate and the metal film by the generated polymer compound.
